(19) United States
(12) Patent Application Publication
(10) Pub. No.: US 2024/0052210 A1
(43) Pub. Date: Feb. 15, 2024

(54) ADHESIVE SHEET AND DISPLAY BODY

(71) Applicant: LINTEC CORPORATION, Tokyo (JP)

(72) Inventors: Sho KOSABA, Tokyo (JP); Yoichi TAKAHASHI, Tokyo (JP)

(73) Assignee: LINTEC CORPORATION, Tokyo (JP)

(21) Appl. No.: 18/277,853

(22) PCT Filed: Oct. 29, 2021
(86) PCT No.: PCT/JP2021/040149

§ 371 Date: Aug. 18, 2023

(30) Foreign Application Priority Data
Feb. 26, 2021 (JP) 2021-030913

(51) Int. Cl. C09J 7/38; C09J 11/04; C09J 7/10; H01L 25/075; B32B 7/12

(52) U.S. Cl. CPC C09J 7/385; C09J 11/04; C09J 7/10; H01L 25/0753; B32B 7/12; G02F 2202/28; G02F 1/133606

(57) ABSTRACT

A pressure sensitive adhesive sheet having a pressure sensitive adhesive layer that includes at least one colored pressure sensitive adhesive layer, the colored pressure sensitive adhesive layer having a pressure sensitive adhesive that contains a colorant, the pressure sensitive adhesive layer having a lightness L* of 90 or less as defined by a CIE 1976 L*a*b* color system, the pressure sensitive adhesive layer having a total luminous transmittance of 3% or more and a thermal conductivity of 0.1 W/m·K or more.

### TECHNICAL FIELD

The present invention relates to a pressure sensitive adhesive sheet suitable for bonding, for example, one or more display body structural members and relates also to a display body using the pressure sensitive adhesive sheet.

### BACKGROUND ART

In modern display bodies (displays), for example, in display bodies of various mobile electronic devices such as smartphones and tablet terminals, display bodies such as for televisions and digital signage, and in-vehicle display bodies of various meters and the like provided on instrument panels, car navigation systems, and consoles of automobiles, it may be required to improve the design properties of a display body by achieving a sense of unity with a peripheral portion of the display body, for example, a frame-like printed portion or a frame material when the display body is turned off.

To this end, it is conceivable to color the display body. Techniques related to coloring of display bodies are disclosed, for example, in Patent Document 1.

### PRIOR ART DOCUMENTS

### Patent Documents

[Patent Document 1] JP2005-82634A

### SUMMARY OF THE INVENTION

### Problems to be Solved By the Invention

The pressure sensitive adhesive sheet disclosed in the above Patent Document 1, however, is colored for the purpose of light blocking/concealing ability, so when the pressure sensitive adhesive sheet is used on the viewer side of a liquid crystal module, the visibility of the displayed image cannot be ensured.

On the other hand, a liquid crystal display device is provided with a backlight that illuminates the display unit of a liquid crystal panel because the liquid crystal panel itself does not emit light when used in the liquid crystal display device. Conventionally, a sidelight type in which the light source is arranged on the side portion of a light guide plate has been generally used as a scheme of arranging the light source for a backlight in a liquid crystal display device. In recent years, from the viewpoint of brightness and contrast of the screen, a direct type backlight has begun to be considered, in which the light source is arranged directly below the display unit. In the direct type backlight, in order to increase the amount of light and make the amount of light uniform, for example, between the center of the screen and the edges of the screen when the backlight is incorporated in a display device, it is considered to provide a number of light emitters, typically light emitting diodes (LEDs), on a substrate.

Unfortunately, however, since the light emitters as described above generate heat when emitting light, there is a risk that members in the vicinity of the light emitters may deteriorate due to the heat.

The present invention has been made in view of such actual circumstances as described above, and objects of the present invention include providing a pressure sensitive adhesive sheet that has excellent heat dissipation properties and allows a display body to have improved design properties and providing a display body that has excellent heat dissipation properties and improved design properties.

### Means for Solving the Problems

To achieve the above objects, first, the present invention provides a pressure sensitive adhesive sheet comprising a pressure sensitive adhesive layer that includes at least one colored pressure sensitive adhesive layer, the colored pressure sensitive adhesive layer comprising a pressure sensitive adhesive that contains a colorant, the pressure sensitive adhesive layer having a lightness L* of 90 or less as defined by a CIE 1976 L*a*b* color system, the pressure sensitive adhesive layer having a total luminous transmittance of 3% or more and a thermal conductivity of 0.1 W/m·K or more (Invention 1).

In the above invention (Invention 1), the pressure sensitive adhesive layer that satisfies the above physical properties, upon application to a display body, can improve the design properties (appearance harmony as an example) of the display body when the display body is turned off. In addition, the total luminous transmittance being 3% or more can ensure the image/video visibility when the display body is turned on. On the other hand, the thermal conductivity being 0.1 W/m·K or more allows the heat dissipation properties to be excellent.

In the above invention (Invention 1), the pressure sensitive adhesive layer may preferably have a haze value of 0.1% or more and 80% or less (Invention 2).

In the above invention (Invention 1, 2), the colorant may be a black-based colorant, and a color difference ΔE* between the pressure sensitive adhesive layer and perfect black may be preferably 90 or less as defined by the CIE 1976 L*a*b* color system, or the colorant may be a white-based colorant, and a color difference ΔE* between the pressure sensitive adhesive layer and perfect white may be preferably 30 or less as defined by the CIE 1976 L*a*b* color system (Invention 3, 4).

In the above invention (Invention 1 to 4), the pressure sensitive adhesive layer may be preferably a laminate of the at least one colored pressure sensitive adhesive layer and at least one colorless pressure sensitive adhesive layer (Invention 5).

In the above invention (Invention 1 to 5), the pressure sensitive adhesive layer may be preferably that for bonding a display body structural member and another display body structural member (Invention 6).

In the above invention (Invention 6), at least one of the display body structural member and the other display body structural member may preferably have a light emitter (Invention 7).

In the above invention (Invention 5), at least one of the display body structural member and the other display body structural member may preferably have irregularities on a surface on a side to be bonded with the pressure sensitive adhesive layer, and the colorless pressure sensitive adhesive layer may be preferably located in the pressure sensitive adhesive layer so as to provide a surface to be in contact with the irregularities of the at least one of the display body structural member and the other display body structural member (Invention 8).

In the above invention (Invention 1 to 8), the pressure sensitive adhesive sheet may preferably comprise: two release sheets; and the pressure sensitive adhesive layer interposed between the two release sheets so as to be in contact with release surfaces of the two release sheets (Invention 9).

Second, the present invention provides a display body comprising: a display body structural member; another display body structural member; and a pressure sensitive adhesive layer that bonds the display body structural member and the other display body structural member to each other, wherein the pressure sensitive adhesive layer is formed of the pressure sensitive adhesive layer of the pressure sensitive adhesive sheet (Invention 1 to 9) (Invention 10).

In the above invention (Invention 10), at least one of the display body structural member and the other display body structural member may preferably have a light emitter (Invention 11).

In the above invention (Invention 10, 11), at least one of the display body structural member and the other display body structural member may preferably have irregularities on a surface on a side to be bonded with the pressure sensitive adhesive layer (Invention 12).

In the above invention (Invention 12), the irregularities may be preferably those due to a plurality of light emitters provided on a substrate (Invention 13).

In the above invention (Invention 10 to 13), the display body may preferably have a black peripheral portion or a white peripheral portion (Invention 14, 15).

### Advantageous Effect of the Invention

The pressure sensitive adhesive sheet according to the present invention has excellent heat dissipation properties and allows the display body to have improved design properties. Moreover, the display body according to the present invention has excellent heat dissipation properties and improved design properties.

### BRIEF DESCRIPTION OF DRAWINGS

FIG. 1 is a cross-sectional view of a pressure sensitive adhesive sheet according to an embodiment of the present invention.

FIG. 2 is a cross-sectional view of a pressure sensitive adhesive sheet according to another embodiment of the present invention.

FIG. 3 is a cross-sectional view of a display body according to an embodiment of the present invention.

FIG. 4 is a cross-sectional view of a display body according to another embodiment of the present invention.

### EMBODIMENTS FOR CARRYING OUT THE INVENTION Hereinafter, one or more embodiments of the present invention will be described.

### Pressure Sensitive Adhesive Sheet

The pressure sensitive adhesive sheet according to an embodiment of the present invention is a pressure sensitive adhesive sheet comprising a pressure sensitive adhesive layer that includes at least one colored pressure sensitive adhesive layer, and the colored pressure sensitive adhesive layer comprises a pressure sensitive adhesive that contains a colorant. The “pressure sensitive adhesive layer that includes at least one colored pressure sensitive adhesive layer” encompasses a pressure sensitive adhesive layer that is composed only of one colored pressure sensitive adhesive layer.

In the pressure sensitive adhesive sheet according to the present embodiment, the lightness L* of the above pressure sensitive adhesive layer as defined by the CIE 1976 L*a*b* color system is preferably 90 or less, the total luminous transmittance of the above pressure sensitive adhesive layer is preferably 3% or more, and the thermal conductivity of the above pressure sensitive adhesive layer is preferably 0.1 W/m·K or more. The measurement methods for the lightness L* and chromaticities a* and b* in the present specification are as described in Testing Examples, which will be described later. The measurement method for the thermal conductivity in the present specification is also as described in Testing Example, which will be described later. The total luminous transmittance in the present specification refers to a value measured according to JIS K7361-1: 1997.

The pressure sensitive adhesive layer that satisfies the above physical properties, upon application to a display body, can improve the design properties (appearance harmony as an example) of the display body when the display body is turned off. Specifically, the display body can be given a sense of unity between the display unit and a black or white peripheral portion, for example, a printed portion (frame-like printed portion) or a frame material, thereby improving the appearance harmony to exhibit a high-class feeling. In addition, the total luminous transmittance being 3% or more can ensure the image/video visibility when the display body is turned on. On the other hand, the thermal conductivity being 0.1 W/m·K or more allows the heat dissipation properties to be excellent. For example, provided that the pressure sensitive adhesive layer in the present embodiment is close to light emitters (e.g., a number of LEDs (especially mini LEDs or micro LEDs) provided on a substrate), even when the light emitters generate heat as they emit light, the generated heat can be dissipated through the pressure sensitive adhesive layer in the present embodiment. This can suppress the thermal deterioration of the pressure sensitive adhesive layer and other members adjacent to the light emitters.

The color shade of a black peripheral portion may be preferably represented by a lightness L* of 0 to 50, a chromaticity a* of −40 to 40, and a chromaticity b* of −40 to 40, may be particularly preferably represented by a lightness L* of 10 to 40, a chromaticity a* of −30 to 30, and a chromaticity b* of −30 to 30, and may be further preferably represented by a lightness L* of 15 to 30, a chromaticity a* of −20 to 20, and a chromaticity b* of −20 to 20. Additionally or alternatively, the color shade of a white peripheral portion may be preferably represented by a lightness L* of 50 to 100, a chromaticity a* of −40 to 40, and a chromaticity b* of −40 to 40, may be particularly preferably represented by a lightness L* of 65 to 98, a chromaticity a* of −30 to 30, and a chromaticity b* of −30 to 30, and may be further preferably represented by a lightness L* of 80 to 95, a chromaticity a* of −20 to 20, and a chromaticity b* of −20 to 20. The pressure sensitive adhesive sheet according to the present embodiment can be suitably used for a display body having such peripheral portions with the above color shades.

The total luminous transmittance of the pressure sensitive adhesive layer may be preferably 3% or more, more preferably 20% or more, particularly preferably 40% or more, and further preferably 50% or more from the viewpoint of the image/video visibility. Although the upper limit of the total luminous transmittance is not particularly limited, it may be usually 100% or less. In consideration of the relationship with the above lightness L*, the upper limit of the total luminous transmittance may be preferably 98% or less, particularly preferably 95% or less, and further preferably 90% or less.

Additionally or alternatively, the lightness L* of the pressure sensitive adhesive layer may be preferably 90 or less and more preferably 88 or less from the viewpoint of improving the design properties in association with the appearance harmony. In particular, from the viewpoint of giving a sense of unity with a black peripheral portion, the lightness L* of the pressure sensitive adhesive layer may be preferably 80 or less and further preferably 75 or less. On the other hand, from the viewpoint of improving the design properties in association with the appearance harmony and from the viewpoint of the visibility of the display body, the lower limit of the lightness L* may be preferably 10 or more, more preferably 25 or more, particularly preferably 50 or more, and further preferably 65 or more. Among them, from the viewpoint of giving a sense of unity with a white peripheral portion, the lower limit of the lightness L* may be preferably 75 or more, particularly preferably 80 or more, and further preferably 85 or more.

Additionally or alternatively, the chromaticity a* of the pressure sensitive adhesive layer as defined by the CIE 1976 L*a*b* color system may be preferably −40 or more, more preferably −30 or more, particularly preferably −20 or more, further preferably −10 or more, and most preferably −5 or more. From another aspect, the chromaticity a* may be preferably 40 or less, more preferably 30 or less, particularly preferably 20 or less, further preferably 10 or less, and most preferably 5 or less. When the chromaticity a* falls within the above range, the design properties, especially appearance harmony, may be further improved.

Additionally or alternatively, the chromaticity b* of the pressure sensitive adhesive layer as defined by the CIE 1976 L*a*b* color system may be preferably −40 or more, more preferably −30 or more, particularly preferably −20 or more, further preferably −10 or more, and most preferably −5 or more. From another aspect, the chromaticity b* may be preferably 40 or less, more preferably 30 or less, particularly preferably 20 or less, further preferably 10 or less, and most preferably 5 or less. When the chromaticity b* falls within the above range, the design properties, especially appearance harmony, may be further improved.

The thermal conductivity of the pressure sensitive adhesive layer may be preferably 0.1 W/m·K or more, more preferably 0.11 W/m·K or more, particularly 0.12 W/m·K or more, and further preferably 0.14 W/m·K or more from the viewpoint of the heat dissipation properties. From another aspect, the thermal conductivity may be preferably 10 W/m·K or less, more preferably 5 W/m·K or less, particularly preferably 1 W/m·K or less, and further preferably 0.2 W/m·K or less.

When the colorant contained in the pressure sensitive adhesive constituting the colored pressure sensitive adhesive layer in the present embodiment is a black-based colorant, a color difference ΔE*(B) between the above pressure sensitive adhesive layer and perfect black may be preferably 90 or less, more preferably 88 or less, particularly preferably 80 or less, and further preferably 75 or less. The color difference ΔE*(B) is defined by the CIE 1976 L*a*b* color system.

The perfect black as defined by the CIE 1976 L*a*b* color system has a lightness L* of 0, a chromaticity a* of 0, and a chromaticity b* of 0. Therefore, when the measured value of lightness L* is L*M, the measured value of chromaticity a* is a*M, and the measured value of b* is b*M for the pressure sensitive adhesive layer, the color difference ΔE*(B) from the perfect black is calculated according to Equation (I) below.

[Mathematical Formula 1]

ΔE*(B)=\sqrt{(L*M)²+(a*M)²+(b*M)²} (I)

Provided that the color difference ΔE*(B) of the above pressure sensitive adhesive layer satisfies the above, when the display body is turned off, the appearance harmony can be exhibited between the display unit and a black peripheral portion, for example, a black printed portion, a black frame material, a black wall, or the like, thus improving the design properties. The black color of the peripheral portion may not have to be the above-described “perfect black.”

The lower limit of the above color difference ΔE*(B) is not particularly limited, and the smallest value is 0, but in consideration of the relationship with the above total luminous transmittance, it may be preferably 20 or more, more preferably 40 or more, particularly preferably 60 or more, and further preferably 70 or more.

On the other hand, when the colorant contained in the pressure sensitive adhesive constituting the colored pressure sensitive adhesive layer in the present embodiment is a white-based colorant, a color difference ΔE*(W) between the above pressure sensitive adhesive layer and perfect white may be preferably 30 or less, more preferably 25 or less, particularly preferably 20 or less, and further preferably 15 or less. The color difference ΔE*(W) is defined by the CIE 1976 L*a*b* color system.

The perfect white as defined by the CIE 1976 L*a*b* color system has a lightness L* of 100, a chromaticity a* of 0, and a chromaticity b* of 0. Therefore, when the measured value of lightness L* is L*M, the measured value of chromaticity a* is a*M, and the measured value of b* is b*M for the pressure sensitive adhesive layer, the color difference ΔE*(W) from the perfect white is calculated according to Equation (II) below.

[Mathematical Formula 2]

ΔE*(W)=\sqrt{(100−L*M)²+(a*M)²+(b*M)²} (II)

Provided that the color difference ΔE*(W) of the above pressure sensitive adhesive layer satisfies the above, when the display body is turned off, the appearance harmony can be exhibited between the display unit and a white peripheral portion, for example, a white printed portion, a white frame material, a white wall, or the like, thus improving the design properties. The white color of the peripheral portion may not have to be the above-described “perfect white.”

The lower limit of the above color difference ΔE*(W) is 0 as the smallest value, but in consideration of the relationship with the above total luminous transmittance, it may be preferably 1 or more, more preferably 3 or more, particularly preferably 5 or more, and further preferably 7 or more.

Here, color tone or the like may differ for each display body structural member, and a combination that can readily enhance the unity of members is preferred, but members with greatly different color shades may also be used, such as a combination of white and black. Thus, even when a black peripheral member and a white peripheral member are combined, for example, the pressure sensitive adhesive layer in the present embodiment tends to exhibit excellent appearance harmony and is excellent in the versatility as a pressure sensitive adhesive sheet. From such a viewpoint, the upper limit of ΔE*(B)/ΔE*(W) may be preferably 10 or less in an embodiment, preferably 8 or less in another embodiment, and preferably 7 or less in still another embodiment. Among them, from the viewpoint of increasing the tendency of good appearance harmony with a black peripheral member, the upper limit may be preferably 6 or less, particularly preferably 4 or less, and further preferably 3 or less. On the other hand, the lower limit of ΔE*(B)/ΔE*(W) is 0 or more and may be preferably 1 or more and more preferably 2 or more. Among them, from the viewpoint of increasing the tendency of good appearance harmony with a white peripheral member, the lower limit may be preferably 3 or more, particularly preferably 5 or more, and further preferably 6 or more.

The haze value of the pressure sensitive adhesive layer in the present embodiment may be preferably 0.1% or more, more preferably 0.5% or more, particularly preferably 1% or more, and further preferably 2% or more. This allows the obtained display body to be more readily given a sense of unity between the display unit and a peripheral portion. From another aspect, the haze value of the pressure sensitive adhesive layer in the present embodiment may be preferably 80% or less, more preferably 60% or less, particularly preferably 40% or less, further preferably 20% or less, and most preferably 5% or less. This allows the total luminous transmittance to readily fall within the above range and also allows the obtained display body to be more readily given a sense of unity between the display unit and a peripheral portion. As used in the present specification, the haze value refers to a value measured according to JIS K7136: 2000.

The above physical properties can be achieved by appropriately selecting the type and content of the colorant contained in the pressure sensitive adhesive constituting the colored pressure sensitive adhesive layer.

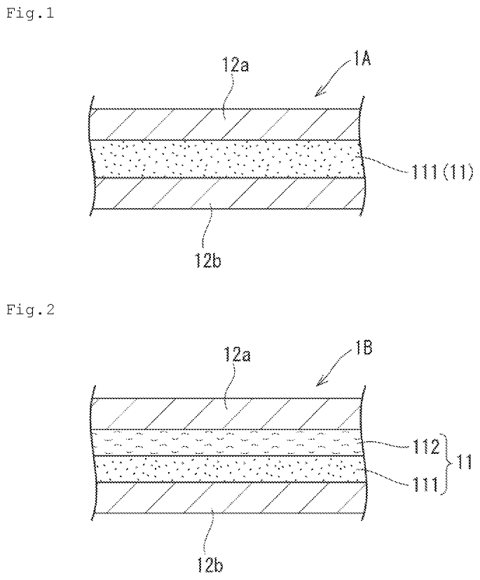

FIG. 1 illustrates a specific configuration as an example of the pressure sensitive adhesive sheet according to an embodiment of the present invention. As illustrated in FIG. 1, a pressure sensitive adhesive sheet 1A is composed of two release sheets 12a and 12b and a pressure sensitive adhesive layer 11 comprising a colored pressure sensitive adhesive layer 111 that is interposed between the two release sheets 12a and 12b so as to be in contact with release surfaces of the two release sheets 12a and 12b. As used in the present specification, the release surface of a release sheet refers to a surface having releasability in the release sheet, and examples of the release surface include both a surface subjected to release treatment and a surface that exhibits releasability even without being subjected to release treatment.

FIG. 2 illustrates a specific configuration as an example of the pressure sensitive adhesive sheet according to another embodiment of the present invention. As illustrated in FIG. 2, a pressure sensitive adhesive sheet 1B is composed of two release sheets 12a and 12b and a pressure sensitive adhesive layer 11 that is interposed between the two release sheets 12a and 12b so as to be in contact with release surfaces of the two release sheets 12a and 12b. The pressure sensitive adhesive layer 11 in the present embodiment is a laminate of one colored pressure sensitive adhesive layer 111 and one colorless pressure sensitive adhesive layer 112. However, the present invention is not limited to this, and the colored pressure sensitive adhesive layer 111 and the colorless pressure sensitive adhesive layer 112 may each have a plurality of layers.

When irregularities are present on an adherend, the colorless pressure sensitive adhesive layer 112 may be preferably located in the above pressure sensitive adhesive layer 11 so as to provide a surface to be in contact with the irregularities of the adherend. When the colored pressure sensitive adhesive layer 111 is brought into contact with the irregularities of the adherend and the irregularities are embedded with the colored pressure sensitive adhesive layer 111, the colored pressure sensitive adhesive layer 111 is compressed and deformed due to the irregularities of the adherend. This makes color gradation in the colored pressure sensitive adhesive layer 111 to cause unevenness of the transmittance. For example, in a portion in which the colored pressure sensitive adhesive layer 111 is compressed, the color may become darker to reduce the transmittance. On the other hand, by having the above configuration, the layer to be in contact with the irregularities of the adherend can be the colorless pressure sensitive adhesive layer 112 rather than the colored pressure sensitive adhesive layer 111. The colored pressure sensitive adhesive layer 111 can therefore be prevented from being compressed or deformed due to the irregularities of the adherend, and it is possible to suppress the uneven transmittance in the pressure sensitive adhesive layer 11.

When the adherend has light emitters that can generate heat, it is also preferred that the colored pressure sensitive adhesive layer 111 should be located in the above pressure sensitive adhesive layer 11 so as to provide a surface on the side close to the light emitters. This allows the colored pressure sensitive adhesive layer 111 to more efficiently exert the excellent heat dissipation properties, and it is possible to more satisfactorily suppress the thermal deterioration of the pressure sensitive adhesive layer 11 and other members adjacent to the light emitters.

### 1. Elements

### 1-1. Pressure Sensitive Adhesive Layer

The colored pressure sensitive adhesive layer 111 may be preferably composed of a pressure sensitive adhesive that contains a colorant. On the other hand, the colorless pressure sensitive adhesive layer 112 may be preferably composed of an adhesive that contains no colorant, and may also be preferably colorless and transparent. “Containing no colorant” means “substantially containing no colorant,” and it encompasses not only a case in which a colorant is not contained at all, but also a case in which a colorant is contained in an amount that does not impair the effects of the present embodiment. The amount may be preferably 0.1 mass % or less, particularly preferably 0.01 mass % or less, further preferably 0.001 mass % or less, and most preferably 0 mass %.

The types of pressure sensitive adhesives constituting the colored pressure sensitive adhesive layer 111 and the colorless pressure sensitive adhesive layer 112 of the pressure sensitive adhesive sheet 1A, 1B according to the present embodiment are not particularly limited, and examples thereof include acrylic-based pressure sensitive adhesives, polyester-based pressure sensitive adhesives, polyurethane-based pressure sensitive adhesives, rubber-based pressure sensitive adhesives, and silicone-based pressure sensitive adhesives. The pressure sensitive adhesive may be any of emulsion type, solvent type, or non-solvent type and may also be crosslinked type or non-crosslinked type. Among these, acrylic-based pressure sensitive adhesives may be preferred because they are excellent in the pressure sensitive adhesive physical properties, optical properties, etc.

The acrylic-based pressure sensitive adhesives may be active energy ray curable or active energy ray non-curable. As the acrylic-based pressure sensitive adhesives, crosslinking type ones may be preferred, and thermal crosslinking type ones may be further preferred.

The type of the pressure sensitive adhesive constituting the colored pressure sensitive adhesive layer 111 and the type of the pressure sensitive adhesive constituting the colorless pressure sensitive adhesive layer 112 may be the same or different. For example, one of them may be an active energy ray curable acrylic-based pressure sensitive adhesive while the other may be an active energy ray non-curable acrylic-based pressure sensitive adhesive. Even when both are common in the active energy ray curable acrylic-based pressure sensitive adhesive or the active energy ray non-curable acrylic pressure sensitive adhesive, the composition of the pressure sensitive adhesive or the monomer composition of the main polymer may be different.

The pressure sensitive adhesive constituting the colored pressure sensitive adhesive layer 111 and the pressure sensitive adhesive constituting the colorless pressure sensitive adhesive layer 112 may be preferably those obtained by crosslinking a pressure sensitive adhesive composition that specifically contains a (meth)acrylic ester polymer (A) and a crosslinker (B) (such a pressure sensitive adhesive composition may be referred to as a “pressure sensitive adhesive composition P,” hereinafter). In the case of the colored pressure sensitive adhesive layer 111, the pressure sensitive adhesive composition P may preferably further contain a colorant (C). When using an active energy ray curable pressure sensitive adhesive as the above pressure sensitive adhesive, the pressure sensitive adhesive composition P may preferably further contain an active energy ray curable component (D).

The pressure sensitive adhesive obtained from such a pressure sensitive adhesive composition P can exhibit desired optical properties, adhesive strength, embedding properties for irregularities (ability to embed irregularities with a pressure sensitive adhesive layer), etc. As used in the present specification, the term “(meth)acrylic acid” refers to both the acrylic acid and the methacrylic acid. The same applies to other similar terms. As used in the present specification, the term “polymer” encompasses the concept of a “copolymer.”

Even after the pressure sensitive adhesive layer 11 is cured by irradiation with active energy rays, the aforementioned physical property values are likely to be satisfied.

### (1) Components of Pressure Sensitive Adhesive Composition

### (1-1) (Meth)acrylic Ester Polymer (A)

The (meth)acrylic ester polymer (A) in the present embodiment may preferably contain, as a monomer unit that constitutes the polymer, a reactive group-containing monomer having in the molecule a reactive group that reacts with the crosslinker (B). The reactive group derived from the reactive group-containing monomer reacts with the crosslinker (B) to form a crosslinked structure (three-dimensional network structure), and a pressure sensitive adhesive having desired cohesive strength can be obtained.

Preferred examples of the above reactive group-containing monomer include a monomer having a hydroxyl group in the molecule (hydroxyl group-containing monomer), a monomer having a carboxy group in the molecule (carboxy group-containing monomer), and a monomer having an amino group in the molecule (amino group-containing monomer). Among these, the hydroxyl group-containing monomer may be preferred because it is excellent in the reactivity with the crosslinker (B).

Examples of the hydroxyl group-containing monomer include hydroxyalkyl (meth)acrylates such as 2-hydroxyethyl (meth)acrylate, 2-hydroxypropyl (meth)acrylate, 3-hydroxypropyl (meth)acrylate, 2-hydroxybutyl (meth) acrylate, 3-hydroxybutyl (meth)acrylate, and 4-hydroxybutyl (meth)acrylate. Among these, hydroxyalkyl (meth)acrylates having a hydroxyalkyl group whose carbon number is 1 to 4 may be preferred from the viewpoints of the reactivity of the hydroxyl group in the obtained (meth)acrylic ester polymer (A) with the crosslinker (B) and the copolymerizability with other monomers. Specifically, for example, 2-hydroxyethyl (meth) acrylate, 4-hydroxybutyl (meth)acrylate, or the like may be preferred, and 2-hydroxyethyl acrylate or 4-hydroxybutyl acrylate may be particularly preferred. These may each be used alone or two or more types may also be used in combination.

Examples of the carboxy group-containing monomer include ethylenically unsaturated carboxylic acids such as acrylic acid, methacrylic acid, crotonic acid, maleic acid, itaconic acid, and citraconic acid. Among these, acrylic acid may be preferred from the viewpoints of the reactivity of the carboxy group in the obtained (meth)acrylic ester polymer (A) with the crosslinker (B) and the copolymerizability with other monomers. These may each be used alone or two or more types may also be used in combination.

Examples of the amino group-containing monomer include aminoethyl (meth)acrylate and n-butylaminoethyl (meth)acrylate. These may each be used alone or two or more types may also be used in combination. Nitrogen atom-containing monomers, which will be described later, are excluded from the amino group-containing monomers.

The (meth)acrylic ester polymer (A) may preferably contain, as the lower limit, 5 mass % or more, particularly preferably 10 mass % or more, and further preferably 15 mass % or more of the reactive group-containing monomer as a monomer unit that constitutes the polymer. From another aspect, the (meth)acrylic ester polymer (A) may preferably contain, as the upper limit, 35 mass % or less, particularly preferably 30 mass % or less, and further preferably 25 mass % or less of the reactive group-containing monomer as a monomer unit that constitutes the polymer. When the (meth)acrylic ester polymer (A) contains the reactive group-containing monomer in the above amount as a monomer unit, a good crosslinked structure is formed in the obtained pressure sensitive adhesive so that the desired cohesive strength is obtained, and the desired physical properties such as gel fraction, storage elastic modulus, and adhesive strength can be readily satisfied.

It is also preferred that the (meth)acrylic ester polymer (A) should not contain a carboxy group-containing monomer as a monomer unit that constitutes the polymer. The carboxyl group is an acid component, so troubles due to the acid may occur on an object to which the pressure sensitive adhesive is bonded, but the absence of a carboxyl group-containing monomer can suppress the troubles (such as corrosion and resistance value change) due to the acid even when there are transparent conductive films such as tin-doped indium oxide (ITO), metal films, or the like. Fortunately, however, it may be permissible to contain a certain amount of the carboxy group-containing monomer to an extent that such problems do not occur. Specifically, the (meth)acrylic ester polymer (A) may be permitted to contain, as a monomer unit, the carboxy group-containing monomer in an amount of 0.1 mass % or less, preferably 0.01 mass % or less, and further preferably 0.001 mass % or less.

The (meth)acrylic ester polymer (A) may preferably contain (meth)acrylic alkyl ester as a monomer unit that constitutes the polymer. This can develop good pressure sensitive adhesive properties. The alkyl group may be linear or branched.

From the viewpoint of the pressure sensitive adhesive properties, (meth)acrylic alkyl ester whose carbon number of alkyl group is 1 to 20 may be preferred as the (meth)acrylic alkyl ester. Examples of the (meth)acrylic alkyl ester whose carbon number of alkyl group is 1 to 20 include methyl (meth)acrylate, ethyl (meth)acrylate, propyl (meth)acrylate, n-butyl (meth)acrylate, n-pentyl (meth)acrylate, n-hexyl (meth) acrylate, 2-ethylhexyl (meth) acrylate, isooctyl (meth)acrylate, n-decyl (meth)acrylate, n-dodecyl (meth)acrylate, myristyl (meth)acrylate, palmityl (meth)acrylate, and stearyl (meth)acrylate. Among these, from the viewpoint of more improving the pressure sensitive adhesive properties, (meth)acrylic alkyl ester whose carbon number of alkyl group is 1 to 8 may be preferred, methyl (meth)acrylate, n-butyl (meth)acrylate, or 2-ethylhexyl (meth)acrylate may be particularly preferred, and methyl methacrylate, n-butyl acrylate, or 2-ethylhexyl acrylate may be particularly preferred. These may each be used alone or two or more types may also be used in combination.

The (meth)acrylic ester polymer (A) may preferably contain 45 mass % or more, particularly preferably 55 mass % or more, and further preferably 65 mass % or more of the (meth)acrylic alkyl ester as a monomer unit that constitutes the polymer. When the lower limit of the content of the (meth)acrylic alkyl ester satisfies the above, the (meth)acrylic ester polymer (A) can exhibit suitable pressure sensitive adhesive properties. On the other hand, the (meth)acrylic ester polymer (A) may preferably contain 99 mass % or less, more preferably 95 mass % or less, particularly preferably 90 mass % or less, and further preferably 85 mass % or less of the (meth)acrylic alkyl ester. When the upper limit of the content of the (meth)acrylic alkyl ester satisfies the above, a suitable amount of other monomer components such as a reactive functional group-containing monomer can be introduced into the (meth)acrylic ester polymer (A).

The above (meth)acrylic ester polymer (A) may also preferably contain a monomer having an alicyclic structure in the molecule (alicyclic structure-containing monomer) as a monomer unit that constitutes the polymer. Since the alicyclic structure-containing monomer is bulky, it is presumed that the presence of such monomers in the polymer widens the distance between the polymers, and the obtained pressure sensitive adhesive can be made excellent in the flexibility. This allows the pressure sensitive adhesive to have excellent embedding properties for irregularities.

The carbon ring of the alicyclic structure in the alicyclic structure-containing monomer may have a saturated structure or may also have an unsaturated bond as a part. The alicyclic structure may be a monocyclic alicyclic structure or may also be a polycyclic alicyclic structure such as a bicyclic or tricyclic structure. From the viewpoints of optimizing the distance between molecules of the obtained (meth)acrylic ester polymer (A) and imparting higher stress relaxation properties to the pressure sensitive adhesive, the above alicyclic structure may be preferably a polycyclic alicyclic structure (polycyclic structure). In consideration of compatibility between the (meth)acrylic ester polymer (A) and other components, the above polycyclic structure may be particularly preferably bicyclic to tetracyclic. From the viewpoint of imparting higher stress relaxation properties to the pressure sensitive adhesive as described above, the carbon number of the alicyclic structure (the number of all carbon atoms in a portion that forms the ring, and when two or more rings are independently present, the total carbon number) may be preferably 5 or more in general and particularly preferably 7 or more. On the other hand, the upper limit of the carbon number of the alicyclic structure is not particularly limited, but may be preferably 15 or less and particularly preferably 10 or less from the viewpoint of compatibility as described above.

Specific examples of the above alicyclic structure-containing monomer include cyclohexyl (meth)acrylate, dicyclopentanyl (meth)acrylate, adamantyl (meth)acrylate, isobornyl (meth)acrylate, dicyclopentenyl (meth)acrylate, and dicyclopentenyloxyethyl (meth)acrylate, among which dicyclopentanyl (meth)acrylate (carbon number of alicyclic structure: 10), adamantyl (meth)acrylate (carbon number of alicyclic structure: 10), or isobornyl (meth)acrylate (carbon number of alicyclic structure: 7) may be preferred because they exhibit more excellent embedding properties for irregularities. In particular, isobornyl (meth)acrylate may be preferred, and isobornyl acrylate may be further preferred. These may each be used alone or two or more types may also be used in combination.

When containing an alicyclic structure-containing monomer as a monomer unit that constitutes the polymer, the (meth)acrylic ester polymer (A) may preferably contain 1 mass % or more, particularly preferably 4 mass % or more, and further preferably 8 mass % or more of the alicyclic structure-containing monomer. From another aspect, the (meth)acrylic ester polymer (A) may preferably contain 30 mass % or less, particularly preferably 20 mass % or less, and further preferably 10 mass % or less of the alicyclic structure-containing monomer as a monomer unit that constitutes the polymer. When the content of the alicyclic structure-containing monomer falls within the above range, the obtained pressure sensitive adhesive readily satisfies the desired physical properties such as gel fraction, storage elastic modulus, and adhesive strength, and is more excellent in the embedding properties for irregularities.

Additionally or alternatively, the (meth)acrylic ester polymer (A) may also preferably contain a nitrogen atom-containing monomer as a monomer unit that constitutes the polymer. By allowing a nitrogen atom-containing monomer to exist in the polymer as a constituent unit, the pressure sensitive adhesive is imparted with a predetermined polarity and can have excellent affinity even for an adherend having a certain degree of polarity, such as glass. As the above nitrogen atom-containing monomer, from the viewpoint of imparting appropriate rigidity to the (meth)acrylic ester polymer (A), a monomer having a nitrogen-containing heterocyclic ring may be preferred. Additionally or alternatively, from the viewpoint of increasing the degree of freedom of the portion derived from the above nitrogen atom-containing monomer in a high-dimensional structure of the pressure sensitive adhesive under construction, it is preferred that the nitrogen atom-containing monomer should not contain a reactive unsaturated double bond group other than one polymerizable group used during the polymerization for forming the (meth)acrylic ester polymer (A).

Examples of the monomer having a nitrogen-containing heterocycle include N-(meth)acryloyl morpholine, N-vinyl-2-pyrrolidone, N-(meth)acryloyl pyrrolidone, N-(meth)acryloyl piperidin, N-(meth)acryloyl pyrrolidine, N-(meth)acryloyl aziridine, aziridinyl ethyl (meth)acrylate, 2-vinylpyridine, 4-vinylpyridine, 2-vinylpyrazine, 1-vinylimidazole, N-vinylcarbazole, and N-vinylphthalimide, among which N-(meth)acryloylmorpholine exhibiting more excellent adhesive strength may be preferred, and N-acryloylmorpholine may be particularly preferred. These may each be used alone or two or more types may also be used in combination.

When containing a nitrogen atom-containing monomer as a monomer unit that constitutes the polymer, the (meth)acrylic ester polymer (A) may preferably contain 1 mass % or more, particularly preferably 2 mass % or more, and further preferably 4 mass % or more of the nitrogen atom-containing monomer. From another aspect, the (meth)acrylic ester polymer (A) may preferably contain 20 mass % or less, particularly preferably 15 mass % or less, and further preferably 10 mass % or less of the nitrogen atom-containing monomer as a monomer unit that constitutes the polymer. When the content of the nitrogen atom-containing monomer falls within the above range, the obtained pressure sensitive adhesive can sufficiently exhibit excellent adhesive strength to glass.

The (meth)acrylic ester polymer (A) may contain other monomers, if desired, as a monomer unit that constitutes the polymer. As other monomers, monomers containing no reactive functional groups may be preferred so as not to inhibit the aforementioned effects of the reactive functional group-containing monomers. Examples of such monomers include alkoxyalkyl (meth)acrylates such as methoxyethyl (meth)acrylate and ethoxyethyl (meth)acrylate, vinyl acetate, and styrene. These may each be used alone or two or more types may also be used in combination.

The (meth)acrylic ester polymer (A) may be preferably a linear polymer. Such a linear polymer may promote the entanglement of molecular chains, and improvement in the cohesive force can be expected; therefore, a pressure sensitive adhesive excellent in the embedding properties for irregularities under high-temperature and high-humidity conditions can readily be obtained.

The (meth)acrylic ester polymer (A) may be preferably a solution polymerization product obtained by a solution polymerization method. Being a solution polymerization product allows a high molecular-weight polymer to be easily obtained, and improvement in the cohesive force can be expected; therefore, a pressure sensitive adhesive excellent in the embedding properties for irregularities under high-temperature and high-humidity conditions can readily be obtained. Moreover, the colorant (C) is easily dispersed well, and the obtained pressure sensitive adhesive tends to satisfy the aforementioned optical properties and thermal conductivity.

The polymerization form of the (meth)acrylic ester polymer (A) may be a random copolymer or may also be a block copolymer.

The weight-average molecular weight of the (meth)acrylic ester polymer (A) may be preferably 100,000 or more, more preferably 200,000 or more, particularly preferably 400,000 or more, and further preferably 500,000 or more as the lower limit. When the lower limit of the weight-average molecular weight of the (meth)acrylic ester polymer (A) satisfies the above, the obtained pressure sensitive adhesive tends to have suitable values such as gel fraction and storage elastic modulus and can be more excellent in the embedding properties for irregularities under high-temperature and high-humidity conditions.

From another aspect, the weight-average molecular weight of the (meth)acrylic ester polymer (A) may be preferably 2,000,000 or less, more preferably 1,400,000 or less, particularly preferably 1,000,000 or less, and further preferably 800,000 or less as the upper limit. When the upper limit of the weight-average molecular weight of the (meth)acrylic ester polymer (A) satisfies the above, the obtained pressure sensitive adhesive tends to have suitable values such as gel fraction and storage elastic modulus and can be more excellent in the initial embedding properties for irregularities. Moreover, the colorant (C) tends to be dispersed well, and the obtained pressure sensitive adhesive can readily satisfy the aforementioned optical properties and thermal conductivity. As used in the present specification, the weight-average molecular weight refers to a standard polystyrene equivalent value that is measured by using a gel permeation chromatography (GPC) method.

In the pressure sensitive adhesive composition P, one type of the (meth)acrylic ester polymer (A) may be used alone or two or more types may also be used in combination.

### (1-2) Crosslinker (B)

The crosslinker (B) can crosslink the (meth)acrylic ester polymer (A) by heating of the pressure sensitive adhesive composition P and can satisfactorily form a three-dimensional network structure. This can improve the cohesive force of the obtained pressure sensitive adhesive, and the embedding properties for irregularities under high-temperature and high-humidity conditions can be excellent.

It suffices that the above crosslinker (B) is reactive with a reactive group of the (meth) acrylic ester polymer (A). Examples of the crosslinker (B) include an isocyanate-based crosslinker, an epoxy-based crosslinker, an amine-based crosslinker, a melamine-based crosslinker, an aziridine-based crosslinker, a hydrazine-based crosslinker, an aldehyde-based crosslinker, an oxazoline-based crosslinker, a metal alkoxide-based crosslinker, a metal chelate-based crosslinker, a metal salt-based crosslinker, and an ammonium salt-based crosslinker. When the reactive group of the (meth)acrylic ester polymer (A) is a hydroxyl group, it may be preferred to use, among the above, the isocyanate-based crosslinker having excellent reactivity with the hydroxyl group. One type of the crosslinker (B) may be used alone or two or more types may also be used in combination.

The isocyanate-based crosslinker contains at least a polyisocyanate compound. Examples of the polyisocyanate compound include aromatic polyisocyanates such as tolylene diisocyanate, diphenylmethane diisocyanate and xylylene diisocyanate, aliphatic polyisocyanates such as hexamethylene diisocyanate, alicyclic polyisocyanates such as isophorone diisocyanate and hydrogenated diphenylmethane diisocyanate, biuret bodies and isocyanurate bodies thereof, and adduct bodies that are reaction products with low molecular active hydrogen-containing compounds such as ethylene glycol, propylene glycol, neopentyl glycol, trimethylol propane, and castor oil. Among these, from the viewpoint of reactivity with hydroxyl groups, trimethylolpropane-modified aromatic polyisocyanate may be preferred, and trimethylolpropane-modified tolylene diisocyanate and trimethylolpropane-modified xylylene diisocyanate may be particularly preferred.

The content of the crosslinker (B) in the pressure sensitive adhesive composition P may be preferably 0.01 mass parts or more, particularly preferably 0.05 mass parts or more, and further preferably 0.1 mass parts or more with respect to 100 mass parts of the (meth)acrylic ester polymer (A). From another aspect, the content may be preferably 10 mass parts or less, more preferably 5 mass parts or less, particularly preferably 1 mass part or less, further preferably 0.5 mass parts or less, and most preferably 0.3 mass parts or less. When the content of the crosslinker (B) falls within the above range, the obtained pressure sensitive adhesive tends to have suitable values such as gel fraction, storage elastic modulus, and adhesive strength and can be more excellent in the embedding properties for irregularities under high-temperature and high-humidity conditions.

### (1-3) Colorant (C)

It may be preferred to select, as the colorant (C), a material that can readily achieve the aforementioned thermal conductivity and has a desired color system. From the viewpoint of readily achieving the thermal conductivity, it may be preferred to select pigments rather than dyes. In general, pigments may be preferably inorganic pigments from the viewpoint of thermal conductivity, but may also be organic pigments. Colors of colorants can be appropriately selected depending on the purpose. For example, when a sense of unity with a black-based peripheral portion is needed, a black-based colorant may be preferably used, while when a sense of unity with a white-based peripheral portion is needed, a white-based colorant may be preferably used.

Preferred examples of usable black-based colorants include black inorganic pigments such as carbon black, copper oxide, black iron oxide, manganese dioxide, and activated carbon. Among these, carbon black may be preferred because of its high thermal conductivity. Preferred examples of usable white-based colorants include white inorganic pigments such as titanium oxide, zinc oxide, calcium carbonate, and aluminum oxide. Among these, titanium oxide may be preferred because of its high thermal conductivity. These inorganic pigments may be subjected to surface treatment such as organic treatment or silicone treatment. Depending on the purpose, the above colorant (C) can be appropriately mixed with one or more other colorants and used.

When the above black-based colorant is diluted 10,000 times with ethyl acetate to obtain a liquid and the haze value of the liquid at a wavelength of 780 nm and the haze value of the liquid at a wavelength of 380 nm are averaged to obtain an average haze, the lower limit of the average haze may be preferably 1% or more, particularly preferably 2% or more, and further preferably 3% or more. From another aspect, the upper limit of the average haze of the above diluted colorant may be preferably 60% or less in an embodiment or 40% or less in another embodiment, particularly preferably 30% or less, further preferably 20% or less, and most preferably 10% or less. By using an appropriate amount of such a black-based colorant, the obtained colored pressure sensitive adhesive layer 111 has suitable optical properties, and therefore the resulting pressure sensitive adhesive layer 11 can readily have suitable optical properties. Moreover, the above color difference ΔE*(B) can readily be satisfied.

When the above black-based colorant is diluted 10,000 times with ethyl acetate to obtain a liquid and the haze value of the liquid at a wavelength of 780 nm and the haze value of the liquid at a wavelength of 380 nm are compared to obtain a difference, the value of the difference may be preferably 30 points or less, more preferably 25 points or less, particularly preferably 20 points or less, further preferably 16 points or less, and most preferably 10 points or less. By using an appropriate amount of such a black-based colorant, the obtained colored pressure sensitive adhesive layer 111 has suitable optical properties, and therefore the resulting pressure sensitive adhesive layer 11 can readily have suitable optical properties. Moreover, the above color difference ΔE*(B) can readily be satisfied.

The lower limit of the above difference between the haze values may be 0 point, but from the viewpoint of facilitating adjustment of the optical properties of the aforementioned pressure sensitive adhesive layer 111 to suitable ones, the lower limit may be preferably 1 point or more, particularly preferably 3 points or more, and further preferably 5 points or more.

When the above black-based colorant is diluted 10,000 times with ethyl acetate to obtain a liquid, the haze value of the liquid at a wavelength of 780 may be preferably 0.1% to 50%, particularly preferably 1% to 30%, further preferably 1.5% to 20%, and most preferably 2% to 10%. Additionally or alternatively, the haze value of the liquid at a wavelength of 380 may be preferably 1% to 60%, particularly preferably 5% to 40%, further preferably 8% to 30%, and most preferably 10% to 20%. This allows the above difference between the haze values to be readily satisfied.

Additionally or alternatively, when the above black-based colorant is diluted 10,000 times with ethyl acetate to obtain a liquid and the haze values of the liquid at 5 nm-pitch wavelengths within a wavelength region of 380 nm to 780 nm (i.e., at wavelengths of 380 nm, 385 nm, 390 nm, . . . , 775 nm, and 780 nm) are determined, the standard deviation of the haze values may be preferably 10 or less, more preferably 8 or less, particularly preferably 5 or less, and further preferably 2 or less. The lower limit of the above standard deviation may be most preferably 0, but usually preferably 0.1 or more, particularly preferably 0.5 or more, and further preferably 1 or more. This allows the obtained colored pressure sensitive adhesive layer 111 to have suitable optical properties, and therefore the resulting pressure sensitive adhesive layer 11 can readily have suitable optical properties.

The mode diameter (modal diameter) of the above white-based colorant may be preferably 2 nm or more, more preferably 10 nm or more, particularly preferably 100 nm or more, and further preferably 200 nm or more. This allows the above color difference ΔE*(W) to be readily satisfied. From another aspect, the above mode diameter may be preferably 3,000 nm or less, more preferably 1,000 nm or less, particularly preferably 800 nm or less, and further preferably 600 nm or less. This allows the obtained pressure sensitive adhesive layer 11 to readily have suitable optical properties.

The median diameter (D50) of the white-based colorant may be preferably 2 nm or more, more preferably 10 nm or more, particularly preferably 100 nm or more, and further preferably 200 nm or more. This allows the above color difference ΔE*(W) to be readily satisfied. From another aspect, the above median diameter may be preferably 3,000 nm or less, more preferably 1,000 nm or less, particularly preferably 800 nm or less, and further preferably 600 nm or less. This allows the obtained pressure sensitive adhesive layer 11 to readily have suitable optical properties.

As used in the present specification, the mode diameter and median diameter of the white-based colorant refer to values measured by a dynamic light scattering method.

In the colored pressure sensitive adhesive layer 111, the content of the colorant (C) with respect to 100 mass parts of the (meth)acrylic ester polymer (A) may be preferably 0.1 mass parts or more, more preferably 0.2 mass parts or more, and particularly preferably 0.3 mass parts or more from the viewpoints of readily satisfying the aforementioned lightness L* and thermal conductivity and obtaining a desired degree of coloring. Among them, when a white-based colorant is used, the above content may be preferably 1 mass part or more and further preferably 2 mass parts or more. Additionally or alternatively, the above content may be preferably 10 mass parts or less, more preferably 5 mass parts or less, and particularly preferably 3 mass parts from the viewpoint of readily satisfying the aforementioned total luminous transmittance (and haze value). Among them, when a black-based colorant is used, the above content may be preferably 2 mass parts or less and further preferably 1 mass part or less.

### (1-4) Active Energy Ray Curable Component (D)

When the pressure sensitive adhesive constituting the colored pressure sensitive adhesive layer 111 or colorless pressure sensitive adhesive layer 112 is an active energy ray curable pressure sensitive adhesive, the pressure sensitive adhesive composition P may preferably contain an active energy ray curable component (D). In a pressure sensitive adhesive obtained by crosslinking the pressure sensitive adhesive composition P and curing it with active energy rays, it is considered that molecules of the active energy ray curable component (D) are polymerized with one another and the polymerized active energy ray curable component (D) is entangled with the crosslinked structure (three-dimensional network structure) of the (meth)acrylic ester polymer (A). The pressure sensitive adhesive having such a high-dimensional structure exhibits extremely excellent durability and is particularly excellent in the embedding properties for irregularities under high-temperature and high-humidity conditions.

The active energy ray curable component (D) is not particularly limited, provided that it can be cured by irradiation with active energy rays and can obtain the above effects, and may be any of a monomer, an oligomer, and a polymer or may also be a mixture thereof. Among these, a polyfunctional acrylate-based monomer may be preferred because it is more excellent in the embedding properties for irregularities under high-temperature and high-humidity conditions.

Examples of the polyfunctional acrylate-based monomer include bifunctional ones such as 1,4-butanediol di(meth)acrylate, 1,6-hexanediol di(meth)acrylate, neopentyl glycol di(meth)acrylate, polyethylene glycol di(meth)acrylate, neopentyl glycol adipate di(meth)acrylate, hydroxypivalic acid neopentyl glycol di(meth)acrylate, dicyclopentanyl di(meth)acrylate, tricyclodecanedimethanol di(meth)acrylate, caprolactone-modified dicyclopentenyl di(meth)acrylate, ethylene oxide-modified phosphoric acid di(meth)acrylate, di(acryloxyethyl) isocyanurate, allylated cyclohexyl di(meth)acrylate, ethoxylated bisphenol A diacrylate, and 9,9-bis[4-(2-acryloyloxyethoxy) phenyl] fluorene; trifunctional ones such as trimethylolpropane tri(meth)acrylate, dipentaerythritol tri(meth)acrylate, propionic acid-modified dipentaerythritol tri(meth)acrylate, pentaerythritol tri(meth)acrylate, propylene oxide-modified trimethylolpropane tri(meth)acrylate, tris(acryloxyethyl) isocyanurate, and s-caprolactone-modified tris-(2-(meth)acryloxyethyl) isocyanurate; tetrafunctional ones such as diglycerin tetra(meth)acrylate and pentaerythritol tetra(meth)acrylate; pentafunctional ones such as propionic acid-modified dipentaerythritol penta(meth)acrylate; and hexafunctional ones such as dipentaerythritol hexa(meth)acrylate and caprolactone-modified dipentaerythritol hexa(meth)acrylate. These may each be used alone or two or more types may also be used in combination. From the viewpoint of compatibility with the (meth)acrylic ester polymer (A), the polyfunctional acrylate-based monomer may preferably have a molecular weight of less than 1,000.

Among the above, from the viewpoint of the embedding properties for irregularities under high-temperature and high-humidity conditions, preferred one may be a polyfunctional acrylate-based monomer containing an isocyanurate structure in the molecule, such as di(acryloxyethyl) isocyanurate, tris(acryloxyethyl) isocyanurate, or s-caprolactone-modified tris-(2-(meth)acryloxyethyl) isocyanurate or a polyfunctional acrylate-based monomer containing a cyclic structure (especially cycloalkane structures) in the molecule, such as tricyclodecanedimethanol (meth)acrylate, more preferred one may be a trifunctional or higher polyfunctional acrylate-based monomer containing an isocyanurate structure in the molecule or a difunctional or higher polyfunctional acrylate-based monomer containing a polycyclic structure (especially cycloalkane polycyclic structure) in the molecule, particularly preferred one may be s-caprolactone-modified tris-(2-(meth)acryloxyethyl) isocyanurate or tricyclodecanedimethanol (meth)acrylate, further preferred one may be s-caprolactone-modified tris-(2-acryloxyethyl) isocyanurate or tricyclodecanedimethanol acrylate, and most preferred one may be s-caprolactone-modified tris-(2-acryloxyethyl) isocyanurate.

The content of the active energy ray curable component (D) in the pressure sensitive adhesive composition P may be preferably 1 mass part or more, particularly preferably 3 mass parts or more, and further preferably 4 mass parts or more as the lower limit with respect to 100 mass parts of the (meth)acrylic ester polymer (A) from the viewpoints that the pressure sensitive adhesive after being cured with active energy rays can have suitable values such as gel fraction and storage elastic modulus and can be more excellent in the embedding properties for irregularities under high-temperature and high-humidity conditions. On the other hand, from the viewpoint of the adhesive force of the pressure sensitive adhesive after being cured with active energy rays, the above content may be preferably 20 mass parts or less, particularly preferably 12 mass parts or less, and further preferably 8 mass parts or less as the upper limit.

### (1-5) Photopolymerization Initiator (E)

When ultraviolet rays are used as the active energy rays for curing the pressure sensitive adhesive composition P, the pressure sensitive adhesive composition P may preferably further contain a photopolymerization initiator (E). By containing the photopolymerization initiator (E) in this way, the active energy ray curable component (D) can be efficiently polymerized, and the polymerization curing time and the irradiation amount of the active energy rays can be reduced.

Examples of such a photopolymerization initiator (E) include benzoin, benzoin methyl ether, benzoin ethyl ether, benzoin isopropyl ether, benzoin-n-butyl ether, benzoin isobutyl ether, acetophenone, dimethylaminoacetophenone, 2,2-dimethoxy-2-phenylacetophenone, 2,2-diethoxy-2-phenylacetophenone, 2-hydroxy-2-methyl-1-phenylpropan-1-one, 1-hydroxycyclohexyl phenyl ketone, 2-methyl-1-[4-(methylthio)phenyl]-2-morpholino-propan-1-one, 4-(2-hydroxyethoxy)phenyl-2-(hydroxy-2-propyl)ketone, benzophenone, p-phenylbenzophenone, 4,4′-diethylaminobenzophenone, dichlorobenzophenone, 2-methylanthraquinone, 2-ethylanthraquinone, 2-tert -butylanthraquinone, 2-aminoanthraquinone, 2-methylthioxanthone, 2-ethylthioxanthone, 2-chlorothioxanthone, 2,4-dimethylthioxanthone, 2,4-diethylthioxanthone, benzyl dimethyl ketal, acetophenone dimethyl ketal, p-dimethylaminobenzoate, oligo[2-hydroxy-2-methyl-1[4-(1-methylvinyl)phenyl]propane], 2,4,6-trimethylbenzoyl-diphenyl-phosphine oxide, and bis(2,4,6-trimethylbenzoyl)-phenylphosphine oxide. These may each be used alone or two or more types may also be used in combination.

Among the above, phosphine oxide-based photopolymerization initiators may be preferred because they are readily cleaved and can readily and reliably cure the pressure sensitive adhesive even when irradiated with ultraviolet rays through a plastic plate containing an ultraviolet absorber. Specifically, 2,4,6-trimethylbenzoyl -diphenyl-phosphine oxide, and bis(2,4,6-trimethylbenzoyl) -phenylphosphine oxide, etc. may be preferred.

The content of the photopolymerization initiator (E) in the pressure sensitive adhesive composition P may be preferably 0.1 mass parts or more, particularly preferably 1 mass part or more, and further preferably 5 mass parts or more as the lower limit with respect to 100 mass parts of the active energy ray-curable component (D). From another aspect, the content may be preferably 30 mass parts or less, particularly preferably 20 mass parts or less, and further preferably 12 mass parts or less as the lower limit.

### (1-6) Various Additives

If desired, the pressure sensitive adhesive composition P can contain one or more of various additives, such as a silane coupling agent, an antirust, an ultraviolet absorber, an antistatic, a tackifier, an antioxidant, a light stabilizer, a softening agent, and a refractive index adjuster, which are commonly used in acrylic-based pressure sensitive adhesives. The additives which constitute the pressure sensitive adhesive composition P are deemed not to include a polymerization solvent or a diluent solvent, which will be described later.

The pressure sensitive adhesive composition P may preferably contain a silane coupling agent among the above. This can improve the interfacial adhesion with an adherend even when the adherend is plastic or glass, and the embedding properties for irregularities under high-temperature and high-humidity conditions can be more excellent.

The silane coupling agent may be preferably an organosilicon compound having at least one alkoxysilyl group in the molecule, which has satisfactory compatibility with the (meth)acrylic ester polymer (A) and light transmittance.

Examples of such a silane coupling agent include polymerizable unsaturated group-containing silicon compounds such as vinyltrimethoxysilane, vinyltriethoxysilane and methacryloxypropyltrimethoxysilane, silicon compounds having an epoxy structure, such as 3-glycidoxypropyltrimethoxysilane and 2-(3,4-epoxycyclohexyl)ethyltrimethoxysilane, mercapto group-containing silicon compounds such as 3-mercaptopropyltrimethoxysilane, 3-mercaptopropyltriethoxysilane and 3-mercaptopropyldimethoxymethylsilane, amino group-containing silicon compounds such as 3-aminopropyltrimethoxysilane, N-(2-aminoethyl)-3-aminopropyltrimethoxysilane and N-(2-aminoethyl)-3-aminopropylmethyldimethoxysilane, 3-chloropropyltrimethoxysilane, 3-isocyanatepropyltriethoxysilane, and condensates of at least one of these and an alkyl group-containing silicon compound such as methyltriethoxysilane, ethyltriethoxysilane, methyltrimethoxysilane and ethyltrimethoxysilane. These may each be used alone or two or more types may also be used in combination.

The content of the silane coupling agent in the pressure sensitive adhesive composition P may be preferably 0.01 mass parts or more, particularly preferably 0.05 mass parts or more, and further preferably 0.1 mass parts or more with respect to 100 mass parts of the (meth)acrylic ester polymer (A). From another aspect, the content may be preferably 1.2 mass parts or less, particularly preferably 0.8 mass part or less, and further preferably 0.4 mass parts or less.

### (2) Preparation of Pressure Sensitive Adhesive Composition

The pressure sensitive adhesive composition P can be prepared through producing the (meth)acrylic ester polymer (A) and mixing the obtained (meth)acrylic ester polymer (A) and the crosslinker (B), and, if desired, adding the active energy ray curable component (D), the photopolymerization initiator (E), etc. In the case of the colored pressure sensitive adhesive layer 111, the colorant (C) may be further compounded.

The (meth)acrylic ester polymer (A) can be produced by polymerizing a mixture of the monomers which constitute the polymer using a commonly-used radical polymerization method. Polymerization of the (meth)acrylic ester polymer (A) may be preferably carried out by a solution polymerization method, if desired, using a polymerization initiator. However, the present invention is not limited to this, and the polymerization may be performed without a solvent. Examples of the polymerization solvent include ethyl acetate, n-butyl acetate, isobutyl acetate, toluene, acetone, hexane, and methyl ethyl ketone, and two or more types thereof may also be used in combination.

Examples of the polymerization initiator include azo-based compounds and organic peroxides and two or more types thereof may also be used in combination. Examples of the azo-based compounds include 2,2′-azobisisobutyronitrile, 2,2′-azobis(2-methylbutyronitrile), 1,1′-azobis(cyclohexane 1-carbonitrile), 2,2′-azobis(2,4-dimethylvaleronitrile), 2,2′-azobis(2,4-dimethyl-4-methoxyvaleronitrile), dimethyl 2,2′-azobis(2-methylpropionate), 4,4′-azobis(4-cyanovaleric acid), 2,2′-azobis(2-hydroxymethylpropionitrile), and 2,2′-azobis[2-(2-imidazolin-2-yl)propane].

Examples of the organic peroxides include benzoyl peroxide, t-butyl perbenzoate, cumene hydroperoxide, diisopropyl peroxydicarbonate, di-n-propyl peroxydicarbonate, di(2-ethoxyethyl)peroxydicarbonate, t-butyl peroxyneodecanoate, t-butyl peroxybivalate, (3,5,5-trimethylhexanoyl)peroxide, dipropionyl peroxide, and diacetyl peroxide.

In the above polymerization step, the weight-average molecular weight of the polymer to be obtained can be adjusted by compounding a chain transfer agent such as 2-mercaptoethanol.

After the (meth)acrylic ester polymer (A) is obtained, the pressure sensitive adhesive composition P (coating solution) diluted with a solvent may be obtained through adding the crosslinker (B) and, if desired, a dilution solvent, the colorant (C), the active energy ray curable component (D), the photopolymerization initiator (E), other additives, etc. to the solution of the (meth)acrylic ester polymer (A) and sufficiently mixing them. If any of the above components is in the form of a solid, or if precipitation occurs when the component is mixed with another component in an undiluted state, the component may be preliminarily dissolved in or diluted with a dilution solvent alone and then mixed with the other component.

Examples of the above dilution solvent for use include aliphatic hydrocarbons such as hexane, heptane and cyclohexane, aromatic hydrocarbons such as toluene and xylene, halogenated hydrocarbons such as methylene chloride and ethylene chloride, alcohols such as methanol, ethanol, propanol, butanol and 1-methoxy-2-propanol, ketones such as acetone, methyl ethyl ketone, 2-pentanone, isophorone and cyclohexanone, esters such as ethyl acetate and butyl acetate, and cellosolve-based solvents such as ethyl cellosolve.

The concentration/viscosity of the coating solution thus prepared is not particularly limited and can be appropriately selected depending on the situation, provided that the concentration/viscosity is within any range in which the coating is possible. For example, the pressure sensitive adhesive composition P may be diluted to a concentration of 10 to 60 mass %. When obtaining the coating solution, the addition of a dilution solvent or the like is not a necessary condition, and the dilution solvent may not be added if the pressure sensitive adhesive composition P has a viscosity or the like that enables the coating. In this case, the pressure sensitive adhesive composition P may be a coating solution in which the polymerization solvent itself for the (meth) acrylic ester polymer (A) is used as a dilution solvent.

### (3) Formation of Pressure Sensitive Adhesive Layer

The colored pressure sensitive adhesive layer 111 and colorless pressure sensitive adhesive layer 112 in the present embodiment may each be preferably made of a pressure sensitive adhesive obtained by crosslinking the pressure sensitive adhesive composition P (a coating layer of the pressure sensitive adhesive composition P). Crosslinking of the pressure sensitive adhesive composition P can be usually performed by heat treatment. Drying treatment when volatilizing a diluent solvent and the like from the coating layer of the pressure sensitive adhesive composition P applied to a desired object can also serve as the above heat treatment.

The heating temperature of the heat treatment may be preferably 50° C. to 150° C. and particularly preferably 70° C. to 120° C. The heating time may be preferably 10 seconds to 10 minutes and particularly preferably 50 seconds to 2 minutes.

After the heat treatment, if necessary, an aging period at an ordinary temperature (e.g., 23° C., 50% RH) for about 1 to 2 weeks may be provided. When the aging period is necessary, the pressure sensitive adhesive is formed after the aging period passes, while when the aging period is not necessary, the pressure sensitive adhesive is formed after the heat treatment.

The above heat treatment (and aging) allows the (meth)acrylic ester polymer (A) to be sufficiently crosslinked via the crosslinker (B).

The pressure sensitive adhesive layer 11 in the pressure sensitive adhesive sheet 1B illustrated in FIG. 2 can be obtained by laminating the colored pressure sensitive adhesive layer 111 and the colorless pressure sensitive adhesive layer 112. The timing of lamination may be before aging each pressure sensitive adhesive layer or after aging. However, in order to more enhance the interfacial adhesion between the colored pressure sensitive adhesive layer 111 and the colorless pressure sensitive adhesive layer 112, it may be preferred to laminate the pressure sensitive adhesive layers before aging them.

### (4) Physical Properties of Pressure Sensitive Adhesive

The pressure sensitive adhesive in the present embodiment may preferably have the following physical properties.

### (4-1) Gel Fraction

The gel fraction of the pressure sensitive adhesive for each of the colored pressure sensitive adhesive layer 111 and the colorless pressure sensitive adhesive layer 112 may be preferably 20% or more, more preferably 30% or more, particularly preferably 40% or more, and further preferably 45% or more as the lower limit. From another aspect, the gel fraction may be preferably 90% or less, more preferably 80% or less, particularly preferably 70% or less, and further preferably 60% or less as the upper limit. When the gel fraction of the pressure sensitive adhesive falls within the above range, the pressure sensitive adhesive exhibits good cohesive force, and the embedding properties for irregularities under high-temperature and high-humidity conditions can be excellent. Moreover, good adhesive strength is developed, and the adhesion property with an adherend can be more excellent. Here, the measurement method for the gel fraction of the pressure sensitive adhesive is as described in the Testing Example, which will be described later.

In the case of an active energy ray curable pressure sensitive adhesive, the gel fraction of the pressure sensitive adhesive after being cured with active energy rays may be preferably 45% or more, more preferably 55% or more, particularly preferably 65% or more, and further preferably 74% or more as the lower limit. From another aspect, the gel fraction may be preferably 100% or less, more preferably 90% or less, particularly preferably 85% or less, and further preferably 80% or less as the upper limit. When the gel fraction of the pressure sensitive adhesive after being cured with active energy rays falls within the above range, the embedding properties for irregularities under high-temperature and high-humidity conditions can be more excellent. Moreover, good adhesive strength is developed, and the adhesion property with an adherend can be more excellent.

### (4-2) Storage Elastic Modulus

The storage elastic modulus at 23° C. of the pressure sensitive adhesive constituting the colored pressure sensitive adhesive layer 111 may be preferably 0.01 MPa or more, more preferably 0.02 MPa or more, particularly preferably 0.03 MPa or more, and further preferably 0.04 MPa or more as the lower limit. When the lower limit of the above storage elastic modulus satisfies the above, the embedding properties for irregularities under high-temperature and high-humidity conditions can be excellent. When the colorless pressure sensitive adhesive layer 112 of the pressure sensitive adhesive sheet 1B illustrated in FIG. 2 is brought into contact with the irregularities of an adherend to follow them, the colorless pressure sensitive adhesive layer 112 may be compressed or deformed due to the irregularities of the adherend. This may lead to a possibility that the colored pressure sensitive adhesive layer 111 will be affected by the compression or deformation of the colorless pressure sensitive adhesive layer 112, but when the lower limit of the above storage elastic modulus satisfies the above, the colored pressure sensitive adhesive layer 111 is less likely to be affected by compression or deformation of the colorless pressure sensitive adhesive layer 112.

The above storage elastic modulus may be preferably 1 MPa or less, more preferably 0.5 MPa or less, particularly preferably 0.2 MPa or less, and further preferably 0.1 MPa or less as the upper limit. When the upper limit of the above storage elastic modulus satisfies the above, good adhesive strength is developed, and the adhesion property with an adherend can be more excellent.

On the other hand, the storage elastic modulus at 23° C. of the pressure sensitive adhesive constituting the colorless pressure sensitive adhesive layer 112 may be preferably 0.01 MPa or more, more preferably 0.02 MPa or more, particularly preferably 0.03 MPa or more, and further preferably 0.04 MPa or more as the lower limit. When the lower limit of the above storage elastic modulus satisfies the above, the embedding properties for irregularities under high-temperature and high-humidity conditions can be excellent.

The above storage elastic modulus may be preferably 1 MPa or less, more preferably 0.5 MPa or less, particularly preferably 0.2 MPa or less, and further preferably 0.1 MPa or less as the upper limit. When the upper limit of the above storage elastic modulus satisfies the above, the initial embedding properties for irregularities can be excellent. Moreover, the irregularities of an adherend can be absorbed by the colorless pressure sensitive adhesive layer 112, and compression or deformation of the colored pressure sensitive adhesive layer 111 due to the irregularities can be readily suppressed.

When the pressure sensitive adhesive constituting the colored pressure sensitive adhesive layer 111 is an active energy ray curable pressure sensitive adhesive, the storage elastic modulus at 23° C. of the pressure sensitive adhesive after being cured with active energy rays may be preferably 0.02 MPa or more, more preferably 0.05 MPa or more, particularly preferably 0.1 MPa or more, and further preferably 0.12 MPa or more as the lower limit. When the lower limit of the above storage elastic modulus satisfies the above, the embedding properties for irregularities under high-temperature and high-humidity conditions can be excellent. From another aspect, the above storage elastic modulus may be preferably 2 MPa or less, more preferably 1 MPa or less, particularly preferably 0.5 MPa or less, and further preferably 0.2 MPa or less as the upper limit. When the upper limit of the above storage elastic modulus satisfies the above, good adhesive strength is developed, and the adhesion property with an adherend can be more excellent.

On the other hand, when the pressure sensitive adhesive constituting the colorless pressure sensitive adhesive layer 112 is an active energy ray curable pressure sensitive adhesive, the storage elastic modulus at 23° C. of the pressure sensitive adhesive after being cured with active energy rays may be preferably 0.02 MPa or more, particularly preferably 0.05 MPa or more, and further preferably 0.1 MPa or more as the lower limit. When the lower limit of the above storage elastic modulus satisfies the above, the embedding properties for irregularities under high-temperature and high-humidity conditions can be excellent. From another aspect, the above storage elastic modulus may be preferably 2 MPa or less, more preferably 1 MPa or less, particularly preferably 0.5 MPa or less, and further preferably 0.2 MPa or less as the upper limit. When the upper limit of the above storage elastic modulus satisfies the above, good adhesive strength is developed, and the adhesion property with an adherend can be more excellent.

As used in the present specification, the storage elastic modulus refers to a value measured at a measurement frequency of 1 Hz by a torsional shear method according to JIS K7244-6. Specifically, it is as described in the Testing Example, which will be described later.

### (5) Thickness of Pressure Sensitive Adhesive Layer

When the pressure sensitive adhesive layer 11 is composed only of the colored pressure sensitive adhesive layer 111 as in the pressure sensitive adhesive sheet 1A illustrated in FIG. 1, the thickness of the colored pressure sensitive adhesive layer 111 (pressure sensitive adhesive layer 11) may be preferably 25 μm or more, more preferably 50 μm or more, particularly preferably 75 μm or more, and further preferably 100 μm or more. From another aspect, the above thickness may be preferably 500 μm or less, more preferably 300 μm or less, particularly preferably 200 μm or less, and further preferably 150 μm or less. When the thickness of the colored pressure sensitive adhesive layer 111 (pressure sensitive adhesive layer 11) falls within the above range, the aforementioned physical properties are readily satisfied in relation to the content of the colorant (C), and it may be easy to obtain a desired degree of coloring and a desired adhesive force. The colored pressure sensitive adhesive layer 111 may be formed as a single layer or may also be formed by laminating a plurality of layers.

On the other hand, when the pressure sensitive adhesive layer 11 includes the colored pressure sensitive adhesive layer 111 and the colorless pressure sensitive adhesive layer 112 as in the pressure sensitive adhesive sheet 1B illustrated in FIG. 2, the thickness of the colored pressure sensitive adhesive layer 111 may be preferably 5 μm or more, more preferably 20 μm or more, particularly preferably 35 μm or more, and further preferably 45 μm or more. From another aspect, the above thickness may be preferably 1,000 μm or less, more preferably 500 μm or less, particularly preferably 200 μm or less, and further preferably 100 μm or less. When the thickness of the colored pressure sensitive adhesive layer 111 falls within the above range, the aforementioned physical properties are readily satisfied in relation to the content of the colorant (C), and it may be easy to obtain a desired degree of coloring and a desired adhesive force.

On the other hand, the thickness of the colorless pressure sensitive adhesive layer 112 (the colorless pressure sensitive adhesive layer located at the surface to be in contact with the irregularities of an adherend) may be preferably larger than the depth or height of the irregularities of the adherend. Usually, the above thickness may be preferably 10 μm or more, more preferably 30 μm or more, particularly preferably 40 μm or more, and further preferably 50 μm or more as the lower limit. When the lower limit of the thickness of the colorless pressure sensitive adhesive layer 112 satisfies the above, the irregularities of the adherend can be absorbed by the colorless pressure sensitive adhesive layer 112, and compression or deformation of the colored pressure sensitive adhesive layer 111 due to the irregularities can be more effectively suppressed. This can more effectively suppress the uneven transmittance in the pressure sensitive adhesive layer 11.

The thickness of the colorless pressure sensitive adhesive layer 112 may be preferably 3,000 μm or less, more preferably 1,000 μm or less, particularly preferably 500 μm or less, and further preferably 200 μm or less as the upper limit. When the upper limit of the thickness of the colorless pressure sensitive adhesive layer 112 satisfies the above, the thickness of the pressure sensitive adhesive layer 11 tends to be suitable. The colorless pressure sensitive adhesive layer 112 may be formed as a single layer or may also be formed by laminating a plurality of layers.

Here, the thickness of the colorless pressure sensitive adhesive layer that is not located at the surface to be in contact with the irregularities of an adherend is not limited to the above range, and can be set to a desired thickness.

When the pressure sensitive adhesive layer 11 includes the colored pressure sensitive adhesive layer 111 and the colorless pressure sensitive adhesive layer 112 as in the pressure sensitive adhesive sheet 1B illustrated in FIG. 2, the thickness of the pressure sensitive adhesive layer 11 can be appropriately set according to its application, but usually, the above thickness may be preferably 25 μm or more, more preferably 50 μm or more, particularly preferably 75 μm or more, and further preferably 100 μm or more as the lower limit. When the lower limit of the thickness of the pressure sensitive adhesive layer 11 satisfies the above, a desired adhesive strength and excellent embedding properties for irregularities can readily be obtained.

The thickness of the pressure sensitive adhesive layer 11 may be preferably 3,000 μm or less, more preferably 1,000 μm or less, particularly preferably 500 μm or less, and further preferably 200 μm or less as the upper limit. When the upper limit of the thickness of the pressure sensitive adhesive layer 11 satisfies the above, workability is good, and appearance failures such as impressions are less likely to occur.

### 1-2. Release Sheets

The release sheets 12a and 12b are to protect the pressure sensitive adhesive layer 11 until the use of the pressure sensitive adhesive sheet 1A, 1B and are removed when using the pressure sensitive adhesive sheet 1A, 1B (pressure sensitive adhesive layer 11). In the pressure sensitive adhesive sheet 1A, 1B according to the present embodiment, one or both of the release sheets 12a and 12bmay not necessarily be required.

Examples of the release sheets 12a and 12b for use include a polyethylene film, a polypropylene film, a polybutene film, a polybutadiene film, a polymethylpentene film, a polyvinyl chloride film, a vinyl chloride copolymer film, a polyethylene terephthalate film, a polyethylene naphthalate film, a polybutylene terephthalate film, a polyurethane film, an ethylene vinyl acetate film, an ionomer resin film, an ethylene-(meth)acrylic acid copolymer film, an ethylene-(meth)acrylic ester copolymer film, a polystyrene film, a polycarbonate film, a polyimide film, and a fluorine resin film. Crosslinked films thereof may also be used. Laminate films each obtained by laminating a plurality of such films may also be used.

It may be preferred to perform release treatment for the release surfaces (in particular, surfaces to be in contact with the pressure sensitive adhesive layer 11) of the release sheets 12a and 12b. Examples of a release agent to be used for the release treatment include alkyd-based, silicone-based, fluorine-based, unsaturated polyester-based, polyolefin-based, and wax-based release agents. One of the release sheets 12a and 12b to be removed first from the pressure sensitive adhesive layer 11 may be preferably an easy release sheet that requires lower peeling force while the other to be removed later may be preferably a tight release sheet that requires higher peeling force.

The thickness of the release sheets 12a and 12b is not particularly limited, but may be usually about 20 to 200 μm.

### 2. Physical Properties

### (1) Adhesive Strength

The adhesive strength of the colored pressure sensitive adhesive layer 111 to soda-lime glass may be preferably 1 N/25 mm or more, more preferably 10 N/25 mm or more, particularly preferably 20 N/25 mm or more, and further preferably 30 N/25 mm or more as the lower limit. When the lower limit of the adhesive strength satisfies the above, the embedding properties for irregularities under high-temperature and high-humidity conditions can be excellent (in the case where the colored pressure sensitive adhesive layer 111 is in contact with the irregularities of an adherend). From another aspect, the adhesive strength of the colored pressure sensitive adhesive layer 111 to soda-lime glass may be preferably 100 N/25 mm or less, more preferably 75 N/25 mm or less, particularly preferably 50 N/25 mm or less, and further preferably 40 N/25 mm or less as the upper limit. When the upper limit of the adhesive strength satisfies the above, good reworkability can be obtained, and in the event of a lamination error, it is possible to reuse the display body structural members, especially expensive display body structural members.

When the pressure sensitive adhesive constituting the colored pressure sensitive adhesive layer 111 is an active energy ray curable pressure sensitive adhesive, the adhesive strength of the colored pressure sensitive adhesive layer 111 after being cured with active energy rays may be preferably 1 N/25 mm or more, more preferably 10 N/25 mm or more, particularly preferably 20 N/25 mm or more, and further preferably 40 N/25 mm or more as the lower limit. From another aspect, the adhesive strength of the colored pressure sensitive adhesive layer 111 after being cured with active energy rays to soda-lime glass may be preferably 100 N/25 mm or less, more preferably 75 N/25 mm or less, and particularly preferably 50 N/25 mm or less as the upper limit. When the adhesive strength falls within the above range, the embedding properties for irregularities under high-temperature and high-humidity conditions can be excellent (in the case where the colored pressure sensitive adhesive layer 111 is in contact with the irregularities of an adherend).

The adhesive strength of the colorless pressure sensitive adhesive layer 112 to soda-lime glass may be preferably 1 N/25 mm or more, more preferably 10 N/25 mm or more, particularly preferably 20 N/25 mm or more, and further preferably 30 N/25 mm or more as the lower limit. When the lower limit of the adhesive strength satisfies the above, the embedding properties for irregularities under high-temperature and high-humidity conditions can be excellent (in the case where the colorless pressure sensitive adhesive layer 112 is in contact with the irregularities of an adherend). From another aspect, the adhesive strength of the colorless pressure sensitive adhesive layer 112 to soda-lime glass may be preferably 100 N/25 mm or less, more preferably 75 N/25 mm or less, and particularly preferably 50 N/25 mm or less as the upper limit. When the upper limit of the adhesive strength satisfies the above, good reworkability can be obtained.

When the pressure sensitive adhesive constituting the colorless pressure sensitive adhesive layer 112 is an active energy ray curable pressure sensitive adhesive, the adhesive strength of the colorless pressure sensitive adhesive layer 112 after being cured with active energy rays to soda-lime glass may be preferably 1 N/25 mm or more, more preferably 10 N/25 mm or more, particularly preferably 20 N/25 mm or more, and further preferably 30 N/25 mm or more as the lower limit. When the lower limit of the adhesive strength satisfies the above, the embedding properties for irregularities under high-temperature and high-humidity conditions can be excellent (in the case where the colorless pressure sensitive adhesive layer 112 is in contact with the irregularities of an adherend). From another aspect, the adhesive strength of the colorless pressure sensitive adhesive layer 112 after being cured with active energy rays to soda-lime glass may be preferably 100 N/25 mm or less, more preferably 75 N/25 mm or less, and particularly preferably 50 N/25 mm or less as the upper limit. When the upper limit of the adhesive strength satisfies the above, good reworkability can be obtained.

As used in the present specification, the adhesive strength refers basically to a peel strength that is measured using a method of 180° peeling according to JIS 20237: 2009. A measurement sample having a width of 25 mm and a length of 100 mm is used. The measurement sample is bonded to an adherend and pressurized at 0.5 MPa and 50° C. for 20 minutes. After that, the measurement sample is left untouched under a condition of 23° C. and 50% RH for 24 hours, and then the measurement is performed at a peel speed of 300 mm/min. The adhesive strength after the active energy ray curing is that when the measurement sample is bonded to an adherend and then cured with active energy rays.

### (2) Irregularity-Embedding Ratio

Properties of the pressure sensitive adhesive layer to embed the irregularities of an adherend, or the embedding properties for irregularities, can be determined using an irregularity-embedding ratio (%) as an indicator. The irregularity-embedding ratio (%) of the pressure sensitive adhesive layer 11 in the present embodiment, which is represented by the following equation, may be preferably 20% or more, particularly preferably 30% or more, and further preferably 40% or more as the lower limit. The upper limit of the above irregularity-embedding ratio is not particularly limited, but it may usually be preferably 80% or less and particularly preferably 70% or less.

Irregularity-embedding ratio (%)={(Height (μm) of protrusions maintaining embedded state without air bubbles, floating, delamination, etc. after prescribed durability test)/(Thickness of pressure sensitive adhesive layer)}×100

The testing method for the irregularity-embedding ratio is as described in the Testing Example, which will be described later. In the case of an active energy ray curable pressure sensitive adhesive, the irregularity-embedding ratio is that when the measurement sample is bonded to an adherend and then cured with active energy rays.

### 3. Production of Pressure Sensitive Adhesive Sheet

An example of producing the pressure sensitive adhesive sheet 1A according to the embodiment illustrated in FIG. 1 may include coating the release surface of one release sheet 12a (or 12b) with a coating solution of the above pressure sensitive adhesive composition P for the colored pressure sensitive adhesive layer 111, performing heat treatment to crosslink the pressure sensitive adhesive composition P to form a coating layer, and then overlapping the release surface of the other release sheet 12b (or 12a) on the coating layer. Here, two or more release sheets with coating layers may be prepared, and a desired number of the coating layers may be bonded. When an aging period is necessary, the above coating layer may become the pressure sensitive adhesive layer 11 after the aging period passes, while when an aging period is not necessary, the above coating layer formed as such may be the pressure sensitive adhesive layer 11. The above pressure sensitive adhesive sheet 1A can thus be obtained. Conditions for the heat treatment and aging are as previously described.

An example of producing the pressure sensitive adhesive sheet 1B according to the embodiment illustrated in FIG. 2 may include coating the release surface of one release sheet 12a with a coating solution of the above pressure sensitive adhesive composition P for forming the colorless pressure sensitive adhesive layer 112 and performing heat treatment to crosslink the pressure sensitive adhesive composition P to form a coating layer, thus obtaining the release sheet 12a with the coating layer. The example may further include coating the release surface of the other release sheet 12bwith the coating solution of the pressure sensitive adhesive composition P for forming the colored pressure sensitive adhesive layer 111 and performing heat treatment to crosslink the pressure sensitive adhesive composition P to form a coating layer, thus obtaining the release sheet 12b with the coating layer. Then, the release sheet 12a with the coating layer and the release sheet 12b with the coating layer are bonded so that both the coating layers are in contact with each other. Here, two or more release sheets with coating layers may be prepared, and a desired number of the coating layers may be bonded in a desired order of lamination. When an aging period is necessary, the above laminated coating layers may become the pressure sensitive adhesive layer 11 after the aging period passes, while when an aging period is not necessary, the above laminated coating layers formed as such may be the pressure sensitive adhesive layer 11. The above pressure sensitive adhesive sheet 1B can thus be obtained, which is a laminate of the colored pressure sensitive adhesive layer 111 and the colorless pressure sensitive adhesive layer 112.

The coating layer for forming the colorless pressure sensitive adhesive layer 112 and the coating layer for forming the colored pressure sensitive adhesive layer 111 may each be interposed between two release sheets, and when the coating layers are bonded, one release sheet may be removed from each of the coating layers.

Examples of the method of coating with the above coating solution of the pressure sensitive adhesive composition P include a bar coating method, a knife coating method, a roll coating method, a blade coating method, a die coating method, and a gravure coating method.

### Display Body

The display body according to an embodiment of the present invention includes a display body structural member, another display body structural member, and a pressure sensitive adhesive layer that bonds the display body structural members to each other. The pressure sensitive adhesive layer is formed of the pressure sensitive adhesive layer of the pressure sensitive adhesive sheet according to any of the above-described embodiments.

At least one of the display body structural member and the other display body structural member may preferably have a light emitter or irregularities on the surface on the side to be bonded with the pressure sensitive adhesive layer. The irregularities may be preferably those due to a plurality of light emitters provided on a substrate. The display body according to the present embodiment may preferably have a black peripheral portion or a white peripheral portion.

Both the display body structural member and the other display body structural member may be rigid bodies. The pressure sensitive adhesive sheet according to the above-described embodiments allows the rigid bodies to be bonded together. As used in the present specification, the term “rigid body” refers to a member whose bendable angle is less than 90° without irreversibly deforming the structure. The angle may be preferably less than 60°, more preferably less than 45°, particularly preferably less than 10°, and further preferably less than 5°. The bendable angle (bending angle) refers to an angle formed between a rigid body and a horizontal surface when the rigid body is placed on the horizontal surface, one end portion is fixed, and the other end portion is raised from the horizontal surface. The rigid body may be composed of a single layer or a single member or may also be composed of two or more layers or two or more members.

The display body according to one or more embodiments of the present invention will now be described with reference to the drawings.

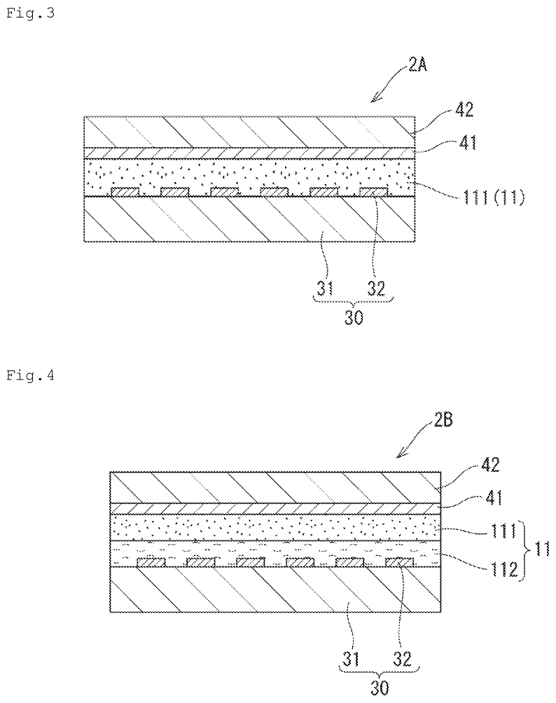

As illustrated in FIG. 3, a display body 2A according to an embodiment of the present invention is configured to include a backlight 30, a pressure sensitive adhesive layer 11 composed of a colored pressure sensitive adhesive layer 111 laminated on the backlight 30, a diffusion member 41 laminated on the pressure sensitive adhesive layer 11, and a liquid crystal panel 42 laminated on the diffusion member 41. The pressure sensitive adhesive layer 11 in this display body 2A is the pressure sensitive adhesive layer 11 of the pressure sensitive adhesive sheet 1A illustrated in FIG. 1.

As illustrated in FIG. 4, a display body 2B according to another embodiment of the present invention includes a backlight 30, a pressure sensitive adhesive layer 11 composed of two or more layers laminated on the backlight 30, a diffusion member 41 laminated on the pressure sensitive adhesive layer 11, and a liquid crystal panel 42 laminated on the diffusion member 41. The pressure sensitive adhesive layer 11 in this display body 2B is the pressure sensitive adhesive layer 11 of the pressure sensitive adhesive sheet 1B illustrated in FIG. 2. The pressure sensitive adhesive layer 11 in the present embodiment is a laminate of a colored pressure sensitive adhesive layer 111 and a colorless pressure sensitive adhesive layer 112, and the colorless pressure sensitive adhesive layer 112 is located on the side in contact with the irregularities due to a plurality of light emitters 32. The above light emitters 32 are sealed without gaps by the colorless pressure sensitive adhesive layer 112. However, the present invention is not limited to this, and the colored pressure sensitive adhesive layer 111 and the colorless pressure sensitive adhesive layer 112 may be replaced with each other. In this case, the colored pressure sensitive adhesive layer 111 in contact with the light emitters 32 further improves the heat dissipation properties.

Here, the backlight 30 in the display body 2A, 2B corresponds to the first display body structural member, and the laminate including the diffusion member 41 and the liquid crystal panel 42 corresponds to the second display body structural member.

The backlight 30 is configured to include at least one substrate 31 and a plurality of light emitters 32 provided on the substrate 31. The backlight 30 has irregularities due to the plurality of light emitters 32.

The substrate 31 is not particularly limited, and those commonly used for backlights may be used. This substrate 31 is usually a printed circuit board (PCB).

The substrate 31 may be integrally formed so that the plurality of light emitters 32 are mounted together, or may also be separately formed so that one light emitter 32 is mounted on one substrate 31. When formed separately, each substrate 31 may be usually fixed to a frame, a support, a housing, or the like. In the present embodiment, as illustrated in FIGS. 3 and 4, the substrate 31 may be preferably formed integrally so that the plurality of light emitters 32 are mounted together.

The surface of the substrate 31 on the pressure sensitive adhesive layer 11 side may be formed with a reflective layer or a reflective member. This can effectively improve the luminance of the backlight 30. Known materials can be used for the reflective layer and the reflective member.

Examples of the types of light emitters 32 include light emitting diodes (LEDs), laser diodes (LDs), organic electroluminescence light emitting elements, and inorganic electroluminescence light emitting elements. Among these, LEDs may be preferred, and mini-LEDs and micro-LEDs may be particularly preferred, from the viewpoint of the sealing properties of the pressure sensitive adhesive layer 11.

The thickness of the light emitters 32 may be preferably 10 μm or more, more preferably 30 μm or more, particularly preferably 50 μm or more, and further preferably 80 μm or more. From another aspect, the thickness of the light emitters 32 may be preferably 300 μm or less, particularly preferably 150 μm or less, and further preferably 100 μm or less.

The width of gaps between adjacent light emitters 32 may be preferably 0.01 mm or more, particularly preferably 0.1 mm or more, and further preferably 0.5 mm or more. From another aspect, the above width of gaps may be preferably 100 mm or less, more preferably 10 mm or less, particularly preferably 4 mm or less, and further preferably 2 mm or less.

The shape of the light emitters 32 is not particularly limited, but it may usually be rectangular parallelepiped, hemispherical, or the like. The size of the light emitters 32 is also not particularly limited, but from the viewpoint of sealing properties for the light emitters, one side or diameter in plan view may be preferably 0.01 to 100 mm, more preferably 0.1 to 10 mm, particularly preferably 0.2 to 5 mm, and further preferably 0.5 to 2 mm.

The diffusion member 41 is a member that diffuses the light emitted from the backlight 30, and this diffusion member 41 can effectively suppress the occurrence of uneven luminance. Known diffusion members can be employed as the diffusion member 41, such as a diffusion plate, a diffusion film, and a combination thereof. Known liquid crystal panels can be employed as the liquid crystal panel 42.

A desired optical member may be provided between the pressure sensitive adhesive layer 11 and the diffusion member 41, between the diffusion member 41 and the liquid crystal panel 42, or on the surface of the liquid crystal panel 42 opposite to the diffusion member 41. Examples of such optical members include luminance enhancement films, contrast enhancement films, viewing angle compensation films, transparent conductive films, liquid crystal polymer films, semi-transmissive reflective films, and anti-scattering films.

To produce the display body 2A according to the embodiment illustrated in FIG. 3, for example, one release sheet 12a of the pressure sensitive adhesive sheet 1A illustrated in FIG. 111 is removed, and the exposed pressure sensitive adhesive layer 11 (colored pressure sensitive adhesive layer 111) is bonded to the surface of the backlight 30 on which the light emitters 32 are present. Then, the other release sheet 12b is removed from the pressure sensitive adhesive layer 11 of the pressure sensitive adhesive sheet 1A, and the exposed pressure sensitive adhesive layer 11 (colored pressure sensitive adhesive layer 111) and the diffusion member 41 are bonded to each other.

To produce the display body 2B according to the embodiment illustrated in FIG. 4, for example, one release sheet 12a of the pressure sensitive adhesive sheet 1B illustrated in FIG. 2 is removed, and the exposed colorless pressure sensitive adhesive layer 112 is bonded to the surface of the backlight 30 on which the light emitters 32 are present. Then, the other release sheet 12b is removed from the pressure sensitive adhesive layer 11 of the pressure sensitive adhesive sheet 1B, and the exposed colored pressure sensitive adhesive layer 111 and the diffusion member 41 are bonded to each other.

In both cases, when the pressure sensitive adhesive layer 11 is active energy ray curable, the pressure sensitive adhesive layer 11 may be irradiated with active energy rays. This allows the energy ray curable component (D) in the pressure sensitive adhesive layer 11 to be polymerized to cure the pressure sensitive adhesive layer 11. Irradiation with energy rays for the pressure sensitive adhesive layer 11 may be usually performed through either the first display body structural member or the second display body structural member.

The active energy rays refer to electromagnetic waves or charged particle radiation having an energy quantum, and specific examples of the active energy rays include ultraviolet rays and electron rays. Among the active energy rays, ultraviolet rays may be particularly preferred because of easy management.

The irradiation with ultraviolet rays can be performed by using a high-pressure mercury lamp, a fusion H lamp, a xenon lamp, or the like. The amount of irradiation with ultraviolet rays, or the illuminance, may be preferably about 50 to 1,000 mW/cm² in an embodiment or preferably about 100 to 500 mW/cm² in another embodiment. The amount of light may be preferably 50 to 10,000 mJ/cm², more preferably 200 to 7,000 mJ/cm², and particularly preferably 500 to 3,000 mJ/cm². On the other hand, the irradiation with electron rays can be performed by using an electron ray accelerator or the like, and the amount of irradiation with electron rays may be preferably about 10 to 10,000 krad.

After that, the diffusion member 41 and the liquid crystal panel 42 are bonded together using a desired pressure sensitive adhesive sheet. As another example, the bonding order of the backlight 30 and the diffusion member 41 may be changed.

Although not illustrated, the display body 2A, 2B according to the present embodiment may preferably have a black peripheral portion or a white peripheral portion. Examples of the peripheral portion include a frame-like printed portion provided around the display unit, a frame material provided around the display unit or the display body, and other members.

In the display body 2A, 2B according to the present embodiment, the pressure sensitive adhesive layer 11 has the aforementioned optical properties, so that the image/video visibility can be ensured when the display body 2A, 2B is turned on, and the design properties (appearance harmony as an example) of the display body 2A, 2B can be improved when the display body 2A, 2B is turned off. Specifically, it is possible to obtain a sense of unity between the display unit and the black or white peripheral portion, thus improving the appearance harmony to exhibit a high-class feeling. Moreover, since the thermal conductivity of the pressure sensitive adhesive layer 11 is the aforementioned value, even when the light emitters 32 of the backlight 30 generate heat as they emit light, the generated heat can be dissipated through the pressure sensitive adhesive layer 11. This can suppress the thermal deterioration of the pressure sensitive adhesive layer 11 and other members adjacent to the light emitters 32.

Furthermore, in the display body 2B illustrated in FIG. 4, the colorless pressure sensitive adhesive layer 112 is laminated on the surface of the backlight 30 having irregularities due to the light emitters 32, and the irregularities are absorbed by the colorless pressure sensitive adhesive layer 112; therefore, the compression or deformation of the colored pressure sensitive adhesive layer 111 can be suppressed. This can suppress uneven transmittance in the pressure sensitive adhesive layer 11.

It should be appreciated that the aforementioned embodiments are described to facilitate understanding of the present invention and are not described to limit the present invention. It is therefore intended that the elements disclosed in the above embodiments include all design changes and equivalents to fall within the technical scope of the present invention.

For example, one or both of the release sheets 12a and 12b in the pressure sensitive adhesive sheet 1A, 1B may be omitted, and one or more desired optical members may be laminated as substitute for the release sheets 12a and/or 12b. Additionally or alternatively, the pressure sensitive adhesive layer 11 may be obtained by laminating the colorless pressure sensitive adhesive layer 112, the colored pressure sensitive adhesive layer 111, and another colorless pressure sensitive adhesive layer 112 in this order.

Additionally or alternatively, in the display body 2B illustrated in FIG. 4, the positions of the colored pressure sensitive adhesive layer 111 and the colorless pressure sensitive adhesive layer 112 may be changed.

### EXAMPLES

Hereinafter, the present invention will be described further specifically with reference to examples, etc., but the scope of the present invention is not limited to these examples, etc.

### Production Example 1 (Preparation of Colored Pressure Sensitive Adhesive Sheet)

### 1. Preparation of (Meth)acrylic Ester Polymer

The (meth)acrylic ester polymer (A) was prepared by using a solution polymerization method to copolymerize 45 mass parts of 2-ethylhexyl acrylate, 20 mass parts of n-butyl acrylate, 10 mass parts of isobornyl acrylate, 5 mass parts of N-acryloylmorpholine, and 20 mass parts of 2-5 hydroxyethyl acrylate. The molecular weight of the (meth)acrylic ester polymer (A) was measured by the method, which will be described later. The weight-average molecular weight (Mw) was 500,000.

### 2. Preparation of Pressure Sensitive Adhesive Composition

The coating solution of a pressure sensitive adhesive composition was obtained through mixing and sufficiently stirring 100 mass parts (solid content equivalent, here and hereinafter) of the (meth)acrylic ester polymer (A) obtained in the above step 1, 0.3 mass parts of trimethylol propane-modified tolylene diisocyanate (available from TOYOCHEM CO., LTD., product name “BHS8515”) as the crosslinker (B), 0.6 mass parts of a carbon black-based black pigment (C1) as the colorant (C), 5.0 mass parts of s-caprolactone-modified tris-(2-acryloxyethyl) isocyanurate (available from SHIN-NAKAMURA CHEMICAL Co., Ltd., product name “NK Ester A-9300-1CL”) as the active energy ray curable component (D), 0.5 mass parts of 2,4,6-trimethylbenzoyl-diphenyl-phosphine oxide as the photopolymerization initiator (E), and 0.3 mass parts of 3-glycidoxypropyltrimethoxysilane as the silane coupling agent and diluting the mixture with methyl ethyl ketone.

Here, Table 1 lists the formulations (solid content equivalents) of the pressure sensitive adhesive compositions when the (meth)acrylic ester polymer (A) is 100 mass parts (solid content equivalent). Details of the simplified names listed in Table 1 and additional information are as follows.

«(Meth)acrylic ester polymer (A)»
2EHA: 2-ethylhexyl acrylate
BA: n-butyl acrylate
MMA: methyl methacrylate
IBXA: isobornyl acrylate
ACMO: N-acryloylmorpholine
HEA: 2-hydroxyethyl acrylate

### «Colorant (C)»

C1: carbon black-based black pigment having physical properties listed in Table 2
C2: titanium oxide-based white pigment
C3: nigrosine-based black dye (available from ORIENT CHEMICAL INDUSTRIES CO., LTD., product name “NUBIAN BLACK PA-2802”)

The composition of C2 (titanium oxide-based white pigment) as the colorant (C) is as follows: 91.2 mass % of titanium oxide; 0.8 mass % of zinc oxide; and 8 mass % of silica. The titanium oxide-based white pigment has a mode diameter of 420 nm and a median diameter of 420 nm. The particle diameter was measured by a dynamic light scattering method (available from MicrotracBEL, device name: Nanotrac Wave).

### 3. Production of Pressure Sensitive Adhesive Sheet

The release-treated surface of a tight release sheet (available from LINTEC Corporation, product name “SP-PET752150”) was coated with the coating solution of the pressure sensitive adhesive composition obtained in the above step 2 by using a knife coater, and heat treatment was performed at 90° C. for 1 minute to form a coating layer (thickness: 50 μm). In the tight release sheet, one surface of a polyethylene terephthalate film was subjected to release treatment with a silicone-based release agent.

Subsequently, the coating layer on the tight release sheet obtained as above and an easy release sheet (available from LINTEC Corporation, product name “SP-PET381031”) obtained by release-treating one surface of a polyethylene terephthalate film with a silicone-based release agent were bonded to each other so that the release-treated surface of the easy release sheet was in contact with the coating layer, and a colored pressure sensitive adhesive sheet was thus prepared, having a configuration of tight release sheet/colored pressure sensitive adhesive layer (a) (thickness: 25 μm)/easy release sheet.

The thickness of the above colored pressure sensitive adhesive layer is a value measured according to JIS K7130 using a constant-pressure thickness meter (available from TECLOCK Co., Ltd., product name “PG-02”) (here and hereinafter).

### Production Examples 2 to 4(Preparation of Colored Pressure Sensitive Adhesive Sheets)

Colored pressure sensitive adhesive sheets having a colored pressure sensitive adhesive layer (b) (Production Example 2), a colored pressure sensitive adhesive layer (c) (Production Example 3), and a colored pressure sensitive adhesive layer (d) (Production Example 4) were prepared in the same manner as in Example 1 except that the composition and ratio of monomers constituting the (meth)acrylic ester polymer (A), the weight-average molecular weight (Mw) of the (meth)acrylic ester polymer (A), the compounding amount of the crosslinker (B), and the type and compounding amount of the colorant (C) were as listed in Table 1.

### Production Examples 5 and 6 (Preparation of Colorless Pressure Sensitive Adhesive Sheets)

Colorless pressure sensitive adhesive sheets having a colorless pressure sensitive adhesive layer (e) (Production Example 5) and a colorless pressure sensitive adhesive layer (f) (Production Example 6) were prepared in the same manner as in Example 1 except that the composition and ratio of monomers constituting the (meth)acrylic ester polymer (A), the weight-average molecular weight (Mw) of the (meth)acrylic ester polymer (A), the compounding amount of the crosslinker (B), the compounding amount of the colorant (C) (not compounded), the compounding amount of the active energy ray curable component (D), the compounding amount of the photopolymerization initiator (E), and the thickness of the pressure sensitive adhesive layer were as listed in Table 1.

The colorless pressure sensitive adhesive layer (f) prepared in Production Example 5 is composed of an active energy ray non-curable pressure sensitive adhesive, and the colorless pressure sensitive adhesive layer (g) prepared in Production Example 6 is also composed of an active energy ray non-curable pressure sensitive adhesive.

The aforementioned weight-average molecular weight (Mw) refers to a weight-average molecular weight that is measured as a polystyrene equivalent value under the following condition using gel permeation chromatography (GPC) (GPC measurement).

### «Measurement Condition»

GPC measurement device: HLC-8020 available from Tosoh Corporation
GPC columns (passing through in the following order): available from Tosoh Corporation
   TSK guard column HXL-H
   TSK gel GMHXL (×2)
   TSK gel G2000HXL
Solvent for measurement: tetrahydrofuran
Measurement temperature: 40° C.

### Example 1

The easy release sheet was removed from the colored pressure sensitive adhesive sheet prepared in Production Example 1 to expose the colored pressure sensitive adhesive layer (a). Likewise, the easy release sheet was removed from the colorless pressure sensitive adhesive sheet prepared in Production Example 6 to expose the colorless pressure sensitive adhesive layer (f). The exposed colored pressure sensitive adhesive layer (a) and colorless pressure sensitive adhesive layer (f) were bonded to each other and then aged for 7 days under a condition of 23° C. and 50% RH.

A pressure sensitive adhesive sheet was thus produced, having a configuration of tight release sheet/colored pressure sensitive adhesive layer (a) (first layer; 50 μm)/colorless pressure sensitive adhesive layer (f) (second layer; 150 μm)/tight release sheet. When the adherend has irregularities, the second layer is the layer on the side in contact with the irregularities of the adherend.

### Examples 2 to 4 and Comparative Examples 1 and 2

Pressure sensitive adhesive sheets were produced in the same manner as in Example 1 except that the pressure sensitive adhesive layers of the first layer and second layer were as listed in Table 4.

### Testing Example 1 (Measurement of Gel Fraction)

The pressure sensitive adhesive sheet produced in each production example was cut into a size of 80 mm×80 mm, the pressure sensitive adhesive layer was wrapped in a polyester mesh (mesh size of 200), the mass was weighed with a precision balance, and the mass of the pressure sensitive adhesive alone was calculated by subtracting the mass of the above mesh itself. The mass at that time is M1.

Then, the pressure sensitive adhesive wrapped in the above polyester mesh was immersed in ethyl acetate at room temperature (23° C.) for 24 hours. After that, the pressure sensitive adhesive was taken out, air-dried under an environment of a temperature of 23° C. and a relative humidity of 50% for 24 hours, and further dried in an oven at 80° C. for 12 hours. After the drying, the mass was weighed with a precision balance, and the mass of the pressure sensitive adhesive alone was calculated by subtracting the mass of the mesh itself. The mass at that time is M2. The gel fraction (%) is represented by (M2/M1)×100. Through this operation, the gel fraction of the pressure sensitive adhesive (before UV) was derived. The results are listed in Table 3.

In addition, each of the pressure sensitive adhesive layers of the pressure sensitive adhesive sheets prepared in Production Examples 1 to 4 and 6 was irradiated with active energy rays (ultraviolet rays; UV) under the following condition through the easy release sheet to cure the pressure sensitive adhesive layer, thus obtaining a cured pressure sensitive adhesive layer. For the pressure sensitive adhesive of the cured pressure sensitive adhesive layer, the gel fraction (after UV) was derived. The results are listed in Table 3.

### «Active Energy Ray Irradiation Condition»

Using a high-pressure mercury lamp
Illuminance of 200 mW/cm2 and light amount of 2,000 mJ/cm2
Using “UVPF-A1” available from EYE GRAPHICS CO., LTD. as a UV illuminance/light amount meter

### Testing Example 2 (Measurement of Storage Elastic Modulus)

The release sheets were removed from each of the pressure sensitive adhesive sheets produced in Production Examples, and a plurality of pressure sensitive adhesive layers were laminated to have a thickness of 3 mm. A cylindrical body (height of 3 mm) having a diameter of 8 mm was punched out from the obtained laminate of the pressure sensitive adhesive layers, and this was used as a sample.

For the above sample, the storage elastic modulus (before UV; MPa) at 23° C. was measured by a torsional shear method according to JIS K7244-6 using a viscoelasticity measurement device (available from Physica, product name “MCR300”) under the following condition. The results are listed in Table 3.
Measurement frequency: 1Hz
Measurement temperature: 23° C.

In addition, for each the pressure sensitive adhesive sheets produced in Production Examples 1 to 4 and 6, the same sample as above was irradiated with active energy rays (ultraviolet rays; UV) under the same condition as in Testing Example 1 to cure the pressure sensitive adhesive, thereby obtaining a sample after irradiation with active energy rays. The storage elastic modulus (after UV; MPa) at 23° C. of the obtained sample after irradiation with active energy rays was measured in the same manner as for the sample before irradiation with active energy rays. The results are listed in Table 3.

### Testing Example 3 (Measurement of Total Luminous Transmittance)

Each of the pressure sensitive adhesive layers of the pressure sensitive adhesive sheets prepared in Production Examples, Examples, and Comparative Examples was bonded to glass, and this was used as a sample for measurement. After performing background measurement on the glass, the total luminous transmittance (%) of the above sample for measurement was measured according to JIS K7361-1: 1997 using a haze meter (available from NIPPON DENSHOKU INDUSTRIES CO., LTD., product name “SH-7000”). The results are listed in Tables 3 and 4.

The pressure sensitive adhesive sheets other than the pressure sensitive adhesive sheet produced in Production Example 5 were irradiated with active energy rays under the same condition as in Testing Example 1 to cure the pressure sensitive adhesive, and then the above measurement was performed.

### Testing Example 4 (Measurement of Haze Value)

For each of the pressure sensitive adhesive layers of the pressure sensitive adhesive sheets prepared in Production Examples, Examples, and Comparative Examples, the haze value (%) was measured according to JIS K7136: 2000 using a haze meter (available from. NIPPON DENSHOKU INDUSTRIES CO., LTD., product name “SH-7000”). The results are listed in Tables 3 and 4.

The pressure sensitive adhesive sheets other than the pressure sensitive adhesive sheet produced in Production Example 5 were irradiated with active energy rays under the same condition as in Testing Example 1 to cure the pressure sensitive adhesive, and then the above measurement was performed.

### Testing Example 5 (Measurement of Adhesive Strength)

The easy release sheet was removed from each of the pressure sensitive adhesive sheets prepared in Production Examples, and the exposed pressure sensitive adhesive layer was bonded to the easy-adhesion layer of a polyethylene terephthalate (PET) film having the easy-adhesion layer (available from TOYOBO CO., LTD., product name “PET A4300,” thickness: 100 μm) to obtain a laminate of release sheet/pressure sensitive adhesive layer/PET film. The obtained laminate was cut into a width of 25 mm and a length of 100 mm, and this was used as a sample.

The tight release sheet was removed from the above sample under an environment of 23° C. and 50% RH, and the exposed pressure sensitive adhesive layer was bonded to soda-lime glass (available from Nippon Sheet Glass Company, Ltd.) and then pressurized in an autoclave available from KURIHARA SEISAKUSHO Co., Ltd. at 0.5 MPa and 50° C. for 20 minutes. After that, the sample was left untouched under a condition of 23° C. and 50% RH for 24 hours, and the adhesive strength (before UV; N/25 mm) was then measured under a condition of a peel speed of 300 mm/min and a peel angle of 180° using a tensile tester (available from ORIENTEC Co., LTD., product name “TENSILON”). The measurement was conducted according to JIS 20237: 2009 except for the condition described herein. The results are listed in Table 3.

In addition, for each of the pressure sensitive adhesive sheets prepared in Production Examples 1 to 4 and 6, the pressure sensitive adhesive layer was bonded to soda lime glass in the same manner as described above, autoclaved, and then left untouched under a condition of 23° C. and 50% RH for 24 hours. After that, the pressure sensitive adhesive sheet was irradiated with active energy rays through the PET film under the same condition as in Testing Example 1 to cure the pressure sensitive adhesive layer. For the cured pressure sensitive adhesive layer, the adhesive strength (after UV; N/25 mm) was measured in the same manner as described above. The results are listed in Table 3.

### Testing Example 6 (Measurement of Irregularity-Embedding Ratio)

An ultraviolet curable ink (available from Teikoku Printing Inks Mfg. Co., Ltd., product name “POS-911 Black”) was screen-printed to have a frame-like shape (outer shape: length 90 mm×breadth 50 mm, width 5 mm) on the surface of a glass plate (available from NSG Precision, product name “Corning Glass Eagle XG,” length 90 mm×breadth 50 mm×thickness 0.5 mm). Then, the above printed ultraviolet curable ink was cured by being irradiated with ultraviolet rays (80 W/cm², two metal halide lamps, lamp height 15 cm, belt speed 10 to 15 m/min), and a stepped glass plate having a step due to printing (the height of step: any one of 5 μm, 10 μm, 15 μm, 20 μm, 25 μm, 50 μm, 60 μm, and 75 μm) was prepared.

The easy release sheet was removed from each of the pressure sensitive adhesive sheets obtained in Production Examples, and the exposed pressure sensitive adhesive layer was bonded to the easy-adhesion layer of a polyethylene terephthalate (PET) film having the easy-adhesion layer (available from TOYOBO CO., LTD., product name “PET A4300,” thickness: 100 μm). Subsequently, the tight release sheet was removed to expose the pressure sensitive adhesive layer. Then, using a laminator (available from HISAGO Co., Ltd./Fujipla, product name “LPD3214”), the above laminate was laminated to each stepped glass plate so that the pressure sensitive adhesive layer covered the entire surface of the frame-like printing, and this was used as a sample for evaluation.

The obtained sample for evaluation was autoclaved under a condition of 50° C. and 0.5 MPa for 30 minutes and then left untouched at normal pressure, 23° C., and 50% RH for 24 hours. The pressure sensitive adhesive sheets produced in Production Examples 1 to 4 and 6 were irradiated with active energy rays under the same condition as in Testing Example 1 through the PET film to cure the pressure sensitive adhesive layer.

Subsequently, the sample was stored for 72 hours under a high-temperature and high-humidity condition of 85° C. and 85% RH (durability test), and then the embedding properties for irregularities were evaluated. The embedding properties for irregularities were determined as to whether or not the step due to printing was completely filled with the pressure sensitive adhesive layer. When air bubbles, floating, delamination, etc. are observed at the interface between the step due to printing and the pressure sensitive adhesive layer, a determination is made that the pressure sensitive adhesive layer cannot follow the irregularities of the step due to printing. Here, the embedding properties for irregularities were evaluated as the irregularity-embedding ratio (%) represented by the following equation. The results are listed in Table 3.

Irregularity-embedding ratio (%)={(Height (μm) of step maintaining embedded state without air bubbles, floating, delamination, etc. after durability test)/(Thickness of pressure sensitive adhesive layer)}×100

### Testing Example 7 (Measurement of L*a*b*)

For each of the pressure sensitive adhesive layers of the pressure sensitive adhesive sheets obtained in Examples and Comparative Examples, the lightness L* (L*M), chromaticity a* (a*M), and b* (b*M) as defined by the CIE 1976 L*a*b* color system were measured in the transmitted light using a simultaneous photometric colorimeter (available from NIPPON DENSHOKU INDUSTRIES CO., LTD., product name “SQ2000”). The results are listed in Table 4.

On the other hand, for each of prepared white printed plate and black printed plate, the lightness L*, chromaticity a*, and b* as defined by the CIE 1976 L*a*b* color system were measured in the reflected light using a simultaneous photometric colorimeter (available from NIPPON DENSHOKU INDUSTRIES CO., LTD., product name “SQ2000”). The results are listed in Table 4.

From the above results, the color difference ΔE*(B) from the perfect black and the color difference ΔE*(W) from the perfect white were calculated according to the following Equation (I) and Equation (II). In addition, ΔE* (B)/ΔE* (W) was calculated by dividing the color difference ΔE*(B) by the color difference ΔE*(W). The results are listed in Table 4.

[Mathematical Formula 3]

ΔE*(B)=\sqrt{(L*M)²+(a*M)²+(b*M)²} (I)

[Mathematical Formula 4]

ΔE*(W)=\sqrt{(100−L*M)²+(a*M)²+(b*M)²} (II)

### Testing Example 8 (Evaluation of Design Properties)

Each of the pressure sensitive adhesive sheets obtained in Examples and Comparative Examples was cut into length 70 mm×breadth 70 mm, and the pressure sensitive adhesive layer of the pressure sensitive adhesive sheet was bonded so as to be interposed between two soda-lime glass plates (available from Nippon Sheet Glass Company, Ltd., length 70 mm×breadth 70 mm×thickness 1.1 mm). Subsequently, the pressure sensitive adhesive layer was cured by being irradiated with ultraviolet rays through one soda-lime glass plate under the same condition as in Testing Example 1 to obtain a cured pressure sensitive adhesive layer, and this was used as a sample.

The obtained sample was placed on a white printed plate (same as in Testing Example 7) as a background. Then, whether the sample was fitted in the background (whether there was a sense of unity with the background) was visually determined under a three-wavelength fluorescent lamp (distance from the fluorescent lamp: 200 cm) to evaluate the design properties (white) according to the following criteria. In addition, the sample was placed on a black printed plate (same as in Testing Example 7) as a background. Then, whether the sample was fitted in the background (whether there was a sense of unity with the background) was visually determined under a three-wavelength fluorescent lamp (distance from the fluorescent lamp: 200 cm) to evaluate the design properties (black) according to the following criteria. The results are listed in Table 4.
A: The sample was very fitted in the background.
B: The sample was fitted in the background to some extent.
C: The sample was clearly not fitted in the background.

The design properties (versatility) were also evaluated according to the following criteria. The results are listed in Table 4.
A: In the evaluation results for the design properties (white) and design properties (black), both were “A” or “B” (excluding both being “B”).
B: In the evaluation results for the design properties (white) and design properties (black), both were “B”.
C: In the evaluation results for the design properties (white) and design properties (black), either was “C” or both were “C.”

### Testing Example 9 (Measurement of Thermal Conductivity)

For each of the pressure sensitive adhesive layers of the pressure sensitive adhesive sheets obtained in Examples and Comparative Examples, measurement of the thermal conductivity (W/m·K) was conducted according to ISO 22007-3 using a thermal diffusivity/conductivity measurement device (available from ai-Phase Co., Ltd., product name “ai-phase mobile”). The results are listed in Table 4.

### Testing Example 10 (Evaluation of Heat Dissipation Properties)

For the heat dissipation properties of the pressure sensitive adhesive sheets obtained in Examples and Comparative Examples, the ratio of thermal conductivity was calculated with reference to the thermal conductivity of the pressure sensitive adhesive sheet of Comparative Example 1 and evaluated according to the following criteria. The results are listed in Table 4.
A: The ratio of thermal conductivity was 150% or more.
B: The ratio of thermal conductivity was 120% or more and less than 150%.
C: The ratio of thermal conductivity was more than 100% and less than 120%.
D: The ratio of thermal conductivity was 100% or less.

### Testing Example 11 (Evaluation of Visibility)

Using a display with a size of 15.6 inches and a resolution of 1366×768 (available from Fujitsu Limited, product name “LITEBOOK A574/H”), black characters (font style: MS P Gothic) were 100%-displayed on a white background at a size of 5 to 20 points (in increments of 1 point).

A sample prepared in the same manner as in Testing Example 10 was placed on the above display. Then, at a position of 50 cm from the display, the size of characters that were visually recognizable was confirmed, and the visibility was evaluated according to the following criteria. The results are listed in Table 4.
A: 8-point characters were visually recognizable.
B: 8-point characters were not completely visually recognizable, but 15-point characters were visually recognizable.
C: 15-point characters were not visually recognizable.

TABLE 1

| | | | | | | | | | | | | | Active | | | |
|---|---|---|---|---|---|---|---|---|---|---|---|---|---|---|---|---|
| | | | | | | | | | | | | | energy | | | |
| | | | | | | | | | Cross- | | | | ray | Photopoly- | Silane | |
| | | | | | | | | | linker | Colorant (C) | | | curable | merization | coupling | |
| | | (Meth)acrylic ester polymer (A) | | | | | | | (B) | C1 | C2 | C3 | component | initiator | agent | Thick- |
| | | Composition | | | | | | | mass | mass | mass | mass | (D) | mass | mass | ness |
| | | 2EHA | BA | MMA | IBXA | ACMO | HEA | Mw | parts | parts | parts | parts | mass parts | parts | parts | μm |
| Production | Colored | 45 | 20 | — | 10 | 5 | 20 | 5075 | 0.3 | 0.6 | — | — | 5 | 0.5 | 0.3 | 50 |
| Example 1 | pressure | | | | | | | | | | | | | | | |
| | sensitive | | | | | | | | | | | | | | | |
| | adhesive | | | | | | | | | | | | | | | |
| | layer (a) | | | | | | | | | | | | | | | |
| Production | Colored | 60 | — | 10 | — | 10 | 20 | 6075 | 0.25 | — | 2.5 | — | 5 | 0.5 | 0.3 | 50 |
| Example 2 | pressure | | | | | | | | | | | | | | | |
| | sensitive | | | | | | | | | | | | | | | |
| | adhesive | | | | | | | | | | | | | | | |
| | layer (b) | | | | | | | | | | | | | | | |
| Production | Colored | 55 | 20 | — | 10 | 5 | 10 | 5075 | 0.2 | 0.3 | — | — | 5 | 0.5 | 0.3 | 50 |
| Example 3 | pressure | | | | | | | | | | | | | | | |
| | sensitive | | | | | | | | | | | | | | | |
| | adhesive | | | | | | | | | | | | | | | |
| | layer (c) | | | | | | | | | | | | | | | |
| Production | Colored | 45 | 20 | — | 10 | 5 | 20 | 5075 | 0.2 | — | — | 1.5 | 5 | 0.5 | 0.3 | 50 |
| Example 4 | pressure | | | | | | | | | | | | | | | |
| | sensitive | | | | | | | | | | | | | | | |
| | adhesive | | | | | | | | | | | | | | | |
| | layer (d) | | | | | | | | | | | | | | | |
| Production | Colorless | 45 | 20 | — | 10 | 5 | 20 | 5075 | 0.2 | — | — | — | — | — | 0.3 | 50 |
| Example 5 | pressure | | | | | | | | | | | | | | | |
| | sensitive | | | | | | | | | | | | | | | |
| | adhesive | | | | | | | | | | | | | | | |
| | layer (e) | | | | | | | | | | | | | | | |
| Production | Colorless | 45 | 20 | — | 10 | 5 | 20 | 5075 | 0.2 | — | — | — | 5 | 0.5 | 0.3 | 150 |
| Example 6 | pressure | | | | | | | | | | | | | | | |
| | sensitive | | | | | | | | | | | | | | | |
| | adhesive | | | | | | | | | | | | | | | |
| | layer (f) | | | | | | | | | | | | | | | |

TABLE 2

| | | | Difference | | |
|---|---|---|---|---|---|
| | 380 nm | 780 nm | between | | Standard |
| | haze | haze | haze | Average | deviation |
| Type of | value | value | values | haze | of haze |
| colorant | (%) | (%) | (points) | (%) | values |
| C1 | 10.1 | 2.3 | 7.8 | 4.11 | 1.49 |

TABLE 3

| | | Gel | | Storage elastic | | | | Adhesive strength | | Irregularity- |
|---|---|---|---|---|---|---|---|---|---|---|
| | | fraction [%] | | modulus [MPa] | | Total | Haze | [N/25 mm] | | embedding |
| | | Before | After | Before | After | luminous | value | Before | After | ratio |
| | | UV | UV | UV | UV | % | % | UV | UV | % |
| Production | Colored pressure | 52 | 72 | 0.06 | 0.13 | 49.2 | 2.9 | 39 | 41 | 40 |
| Example 1 | sensitive adhesive | | | | | | | | | |
| | layer (a) | | | | | | | | | |
| Production | Colored pressure | 49 | 74 | 0.05 | 0.12 | 80.2 | 30.6 | 38 | 44 | 50 |
| Example 2 | sensitive adhesive | | | | | | | | | |
| | layer (b) | | | | | | | | | |
| Production | Colored pressure | 51 | 69 | 0.06 | 0.14 | 71.5 | 1.6 | 40 | 44 | 40 |
| Example 3 | sensitive adhesive | | | | | | | | | |
| | layer (c) | | | | | | | | | |
| Production | Colored pressure | 54 | 70 | 0.06 | 0.15 | 48.8 | 0.3 | 42 | 42 | 40 |
| Example 4 | sensitive adhesive | | | | | | | | | |
| | layer (d) | | | | | | | | | |
| Production | Colorless pressure | 56 | — | 0.08 | — | ≥99 | 0.2 | 43 | — | 40 |
| Example 5 | sensitive adhesive | | | | | | | | | |
| | layer (e) | | | | | | | | | |
| Production | Colorless pressure | 54 | 71 | 0.06 | 0.15 | ≥99 | 0.2 | 51 | 55 | 40 |
| Example 6 | sensitive adhesive | | | | | | | | | |
| | layer (f) | | | | | | | | | |

TABLE 4

| | | | Total | | | | | | |
|---|---|---|---|---|---|---|---|---|---|
| | | | luminous | | | | | | |
| | | | trans- | Haze | | | | | Design |
| | First | Second | mittance | value | | | | [symbol] E*(B)/ | properties |
| | layer | layer | [%] | [%] | L*/a*/b* | ΔE*(B) | ΔE*(W) | [symbol] E*(W) | (white) |
| Example 1 | Colored | Colorless | 48.9 | 2.8 | 73.0/ | 73.1 | 27.2 | 2.7 | B |
| | pressure | pressure | | | −2.4/−1.3 | | | | |
| Example 2 | Colored | Colorless | 80.8 | 30.1 | 87.1/ | 87.1 | 12.9 | 6.8 | A |
| | pressure | pressure | | | 0.1/0.2 | | | | |
| Example 3 | Colored | Colored | 45.4 | 2.0 | 74.2/ | 74.2 | 25.9 | 2.9 | B |
| | pressure | pressure | | | −2.0/−1.2 | | | | |
| Example 4 | Colorless | Colored | 48.8 | 2.9 | 73.0/ | 73.1 | 27.2 | 2.7 | B |
| | pressure | pressure | | | −2.4/−1.3 | | | | |
| Comparative | Colorless | Colorless | ≥99 | 0.2 | 92.3/ | 92.3 | 7.7 | 12.0 | A |
| Example 1 | pressure | pressure | | | −0.3/0.3 | | | | |
| Comparative | Colored | Colorless | 48.3 | 0.4 | 72.2/ | 72.2 | 27.8 | 2.6 | B |
| Example 2 | pressure | pressure | | | 0.2/0.3 | | | | |
| White printed plate | | | — | — | 90.6/ | — | — | — | — |
| | | | | | −0.7/1.0 | | | | |
| Black printed plate | | | — | — | 19.6/ | — | — | — | — |
| | | | | | −0.7/1.8 | | | | |
| | | | | | Design | Design | Thermal | Heat | |
| | | | First | Second | properties | properties | conductivity | dissipation | |
| | | | layer | layer | (black) | (versatility) | [W/m · K] | properties | Visibility |
| | | Example 1 | Colored | Colorless | A | A | 0.125 | B | A |
| | | | pressure | pressure | | | | | |
| | | Example 2 | Colored | Colorless | B | A | 0.146 | A | A |
| | | | pressure | pressure | | | | | |
| | | Example 3 | Colored | Colored | A | A | 0.112 | B | A |
| | | | pressure | pressure | | | | | |
| | | Example 4 | Colorless | Colored | B | B | 0.121 | B | A |
| | | | pressure | pressure | | | | | |
| | | Comparative | Colorless | Colorless | C | C | 0.089 | D | A |
| | | Example 1 | pressure | pressure | | | | | |
| | | Comparative | Colored | Colorless | B | B | 0.086 | D | A |
| | | Example 2 | pressure | pressure | | | | | |

| | | | | | |
|---|---|---|---|---|---|
| White printed plate | — | — | — | — | — |
| Black printed plate | — | — | — | — | — |

As found from Table 4, the pressure sensitive adhesive sheets obtained in Examples were excellent in the design properties and heat dissipation properties and were also excellent in the visibility. Moreover, as found from Table 3, the pressure sensitive adhesive sheets according to Examples obtained by laminating the pressure sensitive adhesive layers produced in respective Production Examples were also excellent in the embedding properties for irregularities.

### INDUSTRIAL APPLICABILITY

The pressure sensitive adhesive sheet of the present invention can be suitably used for bonding or the like of a display body structural member having irregularities due to light emitters and a desired display body structural member, for example, when producing a display body having black and/or white peripheral portions.

### DESCRIPTION OF REFERENCE NUMERALS

1A, 1B Pressure sensitive adhesive sheet
11 Pressure sensitive adhesive layer
111 Colored pressure sensitive adhesive layer
112 Colorless pressure sensitive adhesive layer
12a, 12b Release sheet
2A, 2B Display body
30 Backlight
31 Substrate
32 Light emitter
41 Diffusion member
42 Liquid crystal panel

1. A pressure sensitive adhesive sheet comprising a pressure sensitive adhesive layer that includes at least one colored pressure sensitive adhesive layer,
the colored pressure sensitive adhesive layer comprising a pressure sensitive adhesive that contains a colorant,
the pressure sensitive adhesive layer having a lightness L* of 90 or less as defined by a CIE 1976 L*a*b* color system,
the pressure sensitive adhesive layer having a total luminous transmittance of 3% or more and a thermal conductivity of 0.1 W/m·K or more.

2. The pressure sensitive adhesive sheet according to claim 1, wherein the pressure sensitive adhesive layer has a haze value of 0.1% or more and 80% or less.

3. The pressure sensitive adhesive sheet according to claim 1, wherein
the colorant is a black-based colorant, and
a color difference ΔE* between the pressure sensitive adhesive layer and perfect black is 90 or less as defined by the CIE 1976 L*a*b* color system.

4. The pressure sensitive adhesive sheet according to claim 1, wherein
the colorant is a white-based colorant, and
a color difference ΔE* between the pressure sensitive adhesive layer and perfect white is 30 or less as defined by the CIE 1976 L*a*b* color system.

5. The pressure sensitive adhesive sheet according to claim 1, wherein the pressure sensitive adhesive layer is a laminate of the at least one colored pressure sensitive adhesive layer and at least one colorless pressure sensitive adhesive layer.

6. The pressure sensitive adhesive sheet according to claim 1, wherein the pressure sensitive adhesive layer is that for bonding a display body structural member and another display body structural member.

7. The pressure sensitive adhesive sheet according to claim 6, wherein at least one of the display body structural member and the other display body structural member has a light emitter.

8. The pressure sensitive adhesive sheet according to claim 5, wherein
at least one of the display body structural member and the other display body structural member has irregularities on a surface on a side to be bonded with the pressure sensitive adhesive layer, and
the colorless pressure sensitive adhesive layer is located in the pressure sensitive adhesive layer so as to provide a surface to be in contact with the irregularities of the at least one of the display body structural member and the other display body structural member.

9. The pressure sensitive adhesive sheet according to claim 1, comprising:
two release sheets; and
the pressure sensitive adhesive layer interposed between the two release sheets so as to be in contact with release surfaces of the two release sheets.

10. A display body comprising:
a display body structural member;
another display body structural member; and
a pressure sensitive adhesive layer that bonds the display body structural member and the other display body structural member to each other,
wherein the pressure sensitive adhesive layer is formed of the pressure sensitive adhesive layer of the pressure sensitive adhesive sheet according to claim 1.

11. The display body according to claim 10, wherein at least one of the display body structural member and the other display body structural member has a light emitter.

12. The display body according to claim 10, wherein at least one of the display body structural member and the other display body structural member has irregularities on a surface on a side to be bonded with the pressure sensitive adhesive layer.

13. The display body according to claim 12, wherein the irregularities are those due to a plurality of light emitters provided on a substrate.

14. The display body according to claim 10, having a black peripheral portion.

15. The display body according to claim 10, having a white peripheral portion.
